(19) United States
(12) Patent Application Publication
(10) Pub. No.: US 2025/0356096 A1
(43) Pub. Date: Nov. 20, 2025

(54) CONTEXT SWITCHING SYSTEMS AND METHODS

(71) Applicant: Lattice Semiconductor Corporation, Hillsboro, OR (US)

(72) Inventors: Eric Sivertson, Reno, NV (US); Mauri Delostrinos, San Jose, CA (US); Hoon Choi, Mountain View, CA (US); Joseph Maloney, Los Altos, CA (US); John Gordon Hands, San Jose, CA (US)

(21) Appl. No.: 19/281,534

(22) Filed: Jul. 25, 2025

Related U.S. Application Data
(63) Continuation of application No. PCT/US2024/013242, filed on Jan. 26, 2024.
(60) Provisional application No. 63/481,980, filed on Jan. 27, 2023.

(51) Int. Cl. G06F 30/34

(52) U.S. Cl. CPC G06F 30/34

(57) ABSTRACT

Various techniques are provided to implement context switching systems and methods. In one example, a system includes a plurality of programmable logic devices (PLDs) each configured to be in an active state or an inactive state. At most one of the plurality of PLDs is in the active state to provide PLD functionality. The system further includes an instance controller configured to communicate with each of the plurality of PLDs and control context switch aspects to set each of the plurality of PLDs to the active state or the inactive state. Related methods and devices are provided.

### CROSS-REFERENCE TO RELATED APPLICATION

This application is a continuation of international Patent Application No. PCT/US2024/013242 filed Jan. 26, 2024 and entitled “CONTEXT SWITCHING SYSTEMS AND METHODS,” which in turn claims the benefit of and priority to U.S. Provisional Patent Application No. 63/481,980 filed Jan. 27, 2023 and entitled “CONTEXT SWITCHING SYSTEMS AND METHODS,” which are incorporated herein by reference in their entirety.

### TECHNICAL FIELD

The present invention relates generally to programmable logic devices and, more particularly, to context switching systems and methods.

### BACKGROUND

Programmable logic devices (PLDs) (e.g., field programmable gate arrays (FPGAs), complex programmable logic devices (CPLDs), field programmable systems on a chip (FPSCs), or other types of programmable devices) may be configured with various user designs to implement desired functionality. Typically, the user designs are synthesized and mapped into configurable resources, including by way of non-limiting example programmable logic gates, look-up tables (LUTs), embedded hardware, interconnections, and/or other types of resources, available in particular PLDs. Physical placement and routing for the synthesized and mapped user designs may then be determined to generate configuration data for the particular PLDs. The generated configuration data is loaded into configuration memory of the PLDs to implement the programmable logic gates, LUTs, embedded hardware, interconnections, and/or other types of configurable resources.

### SUMMARY

In one embodiment, a system includes a plurality of PLDs each configured to be in an active state or an inactive state. At most one of the plurality of PLDs is in the active state to provide PLD functionality. The system further includes an instance controller configured to communicate with each of the plurality of PLDs and control context switch aspects to set each of the plurality of PLDs to the active state or the inactive state.

In another embodiment, a method includes operating a first PLD of a plurality of PLDs to provide PLD functionality according to first configuration data loaded in the first PLD. The first PLD of the plurality of PLDs is in an active state and the remaining one or more PLDs of the plurality of PLDs is in an inactive state. At most one of the plurality of PLDs is in the active state to provide PLD functionality. The method further includes performing a context switch from the first PLD to a second PLD of the plurality of PLDs to set the first PLD to the inactive state and the second PLD to the active state to switch operation from the first PLD to the second PLD. The method further includes operating the second PLD after the performing to provide PLD functionality according to second configuration data loaded in the second PLD.

### BRIEF DESCRIPTION OF THE DRAWINGS

FIG. 1 illustrates a block diagram of a PLD in accordance with one or more embodiments of the present disclosure.

FIG. 2 illustrates a block diagram of a programmable logic block of a PLD in accordance with one or more embodiments of the present disclosure.

FIG. 3 illustrates a design process for a PLD in accordance with one or more embodiments of the present disclosure.

FIG. 4 illustrates an example context switch device/architecture in accordance with one or more embodiments of the present disclosure.

FIG. 5 illustrates another example context switch device/architecture in accordance with one or more embodiments of the present disclosure.

FIG. 6 illustrates a flow diagram of an example process for context switching in accordance with one or more embodiments of the present disclosure.

FIG. 7 illustrates a flow diagram of an example operation flow for a context switch device in accordance with one or more embodiments of the present disclosure.

FIG. 8 illustrates a flow diagram of an example process for configuration and activation during boot up in accordance with one or more embodiments of the present disclosure.

FIG. 9 illustrates a flow diagram of an example process for falling back to a golden image during boot up in accordance with one or more embodiments of the present disclosure.

FIG. 10 illustrates a flow diagram of another example process for falling back to a golden image during boot up in accordance with one or more embodiments of the present disclosure.

FIG. 11 illustrates a flow diagram of an example process for configuration of a PLD after boot up in accordance with one or more embodiments of the present disclosure.

FIG. 12 illustrates a flow diagram of an example process for halting and restarting configuration of a PLD in accordance with one or more embodiments of the present disclosure.

FIG. 13 illustrates a flow diagram of an example process for restarting configuration of a PLD after configuration failure in accordance with one or more embodiments of the present disclosure.

FIG. 14 illustrates a flow diagram of an example process for context switching from one PLD to another PLD in accordance with one or more embodiments of the present disclosure.

FIG. 15 illustrates a timing diagram associated with context switching from the one PLD to another PLD in accordance with one or more embodiments in the present disclosure.

FIG. 16 illustrates an example context switch device/architecture in accordance with one or more embodiments of the present disclosure.

FIG. 17 illustrates example context switching connections between instances in accordance with one or more embodiments of the present disclosure.

FIG. 18 illustrates a flow diagram of an example operation flow for a context switch device with second lock control in accordance with one or more embodiments of the present disclosure.

FIG. 19 illustrates examples of instance identification pins in accordance with one or more embodiments of the present disclosure.

FIG. 20 illustrates various context switching functions in accordance with one or more embodiments of the present disclosure.

FIG. 21 illustrates an example multiplexing function in accordance with one or more embodiments of the present disclosure.

FIG. 22 shows the multiplexing function of FIG. 21 with a first mode enabled in accordance with one or more embodiments of the present disclosure.

FIG. 23 shows the multiplexing function of FIG. 21 with a second mode enabled in accordance with one or more embodiments of the present disclosure.

FIG. 24 summarizes various cross couple communication schemes in accordance with one or more embodiments of the present disclosure.

FIG. 25 illustrates an example virtual input/output as set forth in accordance with one or more embodiments of the present disclosure.

FIG. 26 illustrates example boot-up connections in accordance with one or more embodiments of the present disclosure.

FIG. 27 summarizes an example context switching configuration and boot control flow in accordance with one or more embodiments of the present disclosure.

FIG. 28 illustrates an example operation associated with input/output switchover in accordance with one or more embodiments of the present disclosure.

FIG. 29 illustrates an example user flash memory protection scheme in accordance with one or more embodiments of the present disclosure.

FIG. 30 illustrates a flow diagram of an example process for context switching from one PLD to another PLD in accordance with one or more embodiments of the present disclosure.

FIG. 31 illustrates a bridge functional diagram in accordance with one or more embodiments of the present disclosure.

FIG. 32 illustrates a bridge block diagram in accordance with one or more embodiments of the present disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION

In accordance with embodiments disclosed herein, various techniques are provided to implement context switching using context switch devices. In some embodiments, a context switch device/architecture includes an instance controller and multiple logic instances (e.g., also referred to as instances). The instance controller may allow a user to configure (e.g., securely configure) multiple design logic instances (e.g., multiple separate design logic instances) on a single device. A context switch from a first logic instance to a second logic instance involves a switchover from operating using the first logic instance (e.g., to provide functionality according to a first user design loaded in the first logic instance) to operating using the second logic instance (e.g., to provide functionality according to a second user design loaded in the first logic instance that may be the same or different from the first user design).

In some embodiments, the switchover from operating using the first logic instance to using the second logic instance may be near instantaneous. As an example, the switchover may occur in a single clock cycle in some cases in which PLD functionality (e.g., also referred to as user logic functionality or logic functionality) is provided by the first logic instance at a first clock cycle and then PLD functionality is provided by the second logic instance at a second clock cycle adjacent (e.g., temporally adjacent) to the first clock cycle. In at least such cases, the context switch device may be referred to as a rapid context switch (RCS) device.

In some embodiments, only one of the instances is active at a time in the context switch device/architecture. When an instance is active, the instance provides its PLD functionality (e.g., according to its user design logic) and has control of (e.g., actively owns, has write access to) input/outputs (I/Os) of a sharedI/Obank. The inactive instances do not provide their PLD functionality. In some cases, inactive instances (e.g., also referred to as non-active instances) may be in a listen mode to receive instructions to be configured or reconfigured and/or participate in a context switch, receive data (e.g., synchronization data) from the active instance to facilitate a context switch, monitor certain inputs/outputs, and/or other operations.

In some aspects, to facilitate fast context switching, a currently active instance may generate and store synchronization data that is read by a next active instance (e.g., while this next active instance is still an inactive instance) prior to activating this next active instance. As an example, consider that instanceOis a current active instance and instance 1 is a next active instance. Once instance 1 is synchronized to instance 0, instance 1 can immediately/seemlessly replace instance O in providing PLD functionality once instance O is deactivated and instance 1 is activated. In one case, instance 1 may be loaded with the same configuration data as instance 0. InstanceOmay be deactivated and reconfigured with an updated version of a user design (e.g., reconfigured with a configuration bitstream of this updated user design) such that at a subsequent time a switchover may be performed from instance 1 back to instance O for instance O to provide PLD functionality according to the updated version of the user design.
A context switch device according to various embodiments may provide capabilities such as running identical redundant functions in each instance (e.g., for facilitating lockstep operation of the instances), running different functions in each instance (e.g., change PLD functionality on-the-fly by context switching between instances), achieving substantially zero downtime during a system update, reconfiguring one instance while operating another instance, allowing nearly instantaneous/rapid context switch from one instance to another instance, and/or avoiding a need to partition the design into physical regions.

Each logic instance may contain a certain number of logic cells (LCs). In some aspects, each instance may contain the same number of LCs. As a non-limiting example, each instance of the context switch device may include around tens of thousands or hundreds of thousands of LCs, although each instance may include fewer or more LCs as needed for a desired application. In some embodiments, each logic instance is implemented using a PLD. PLDs, such as FPGAs, include configuration memory cells used to control functions desired from PLD logic. The PLDs may include an array of the configuration memory cells arranged in rows and columns and usable to store configuration data. The configuration memory cells may be volatile memory cells, such as random access memory (RAM) cells. In such cases, the configuration memory cells may be referred to as configuration random access memory (CRAM) cells. The CRAM cells may be static RAM (SRAM) cells. The configuration memory cells may be used to implement the PLD's programmable logic cells (PLCs), embedded block RAM (EBR) blocks, digital signal processing (DSP) blocks, etc. In the PLCs, the configuration memory cells may implement LUTs, input switch box (ISB)/output switch box (OSB) routing selection, and other associated logic functions.

Context switching techniques provided herein are different relative to conventional partial reconfiguration techniques. Partial reconfiguration requires a static programmable logic region that is pre-configured to set up partial reconfiguration controls. Other programmable logic regions may be reconfigurable, but the framework to enable such reconfigurability is static and not reconfigurable without a complete reboot/reload. In partial reconfiguration, functionality of the programmable logic is interrupted (e.g., loses continuity), for example, when the static region needs to be updated.

For context switching according to embodiments herein, a PLD's previously configured programmable logic may be completely reconfigured rather than partially reconfigured as in partial reconfiguration. According to various embodiments, context switching (e.g., rapid context switching) allows for continuing uninterrupted coverage of key functions during the complete reconfiguration. In this regard, the key functions may be performed with no loss of continuity when context switching is performed since the context switching causes a switchover from performing PLD functionality, including the key functions, by a first PLD as the active instance to performing PLD functionality, including the key functions, by a second PLD as the active instance. In some aspects, key functions may include, by way of non-limiting example, secure configuration and joint test action group (JTAG), soft error correct, bitstream security (e.g., elliptic curve digital signature algorithm (ECDSA)/advanced encryption standard (AES) bitstream security), user mode security, and/or dual instance with context switching.

In some aspects, such context switching between instances may allow for use in security and safety critical functions, as the instances may collectively be relied upon under any and all reconfigurations due to the complete reconfiguring that may be performed on each instance. In some cases, an instance may provide platform firmware resiliency (PFR) functionality. Such PFR functionality may be controlled by a system (e.g., external system) and firmware and may include, by way of non-limiting example, authenticating images for baseboard management controller (BMC) and FPGA/platform controller hub (PCH) and image recovery; serial peripheral interface (SPI) flash monitoring and protection, event logging, and I2C monitor; and/or other functionality.

In some embodiments, safety and security may be facilitated by having two or more completely separate logic instances/regions. In some applications, the separate logic instances/regions may provide redundant complete systems. An architecture in which the logic instances/regions are used to provide redundant complete systems avoids a single point failure mechanism. In contrast, in the framework provided to facilitate partial reconfiguration, an error or fault in the static region (i.e., a single point failure) may directly cause failure in any redundant partial regions. A context switch device/architecture according to various embodiments may be extended to include additional instances/regions (e.g., more than two instances/regions). As an example, a context switch device/architecture extended to have three or five instances/regions may support/facilitate a high-level safety critical or security critical system that may be implemented with multiple odd number voting schemas (e.g., triple module redundancy (TMR)). In some aspects, complete regions can be put into lockstep to provide safety and security. In some cases, regions can monitor each other, thus allowing for performing of a cross-check without a single point failure as in the case of conventional partial reconfiguration static regions. Such cross-check and monitoring functions may be for functional safety and/or security. In some cases, anti-tamper features may be added to each independent region, thus giving a more complete and holistic coverage unachievable with partial reconfiguration that can rely upon the static region (which is associated with a single failure problem) for its anti-tampering features to be fed into the partial reconfiguration regions.

Although the foregoing describes various examples in which user functions are related to system safety and/or security, the user functions for loading into logical instances may generally be user functions for any desired applications. The user functions are appropriately designed to allow for context switching functionality (e.g., via interconnections and interoperability with an instance controller(s)) in accordance with one or more embodiments.

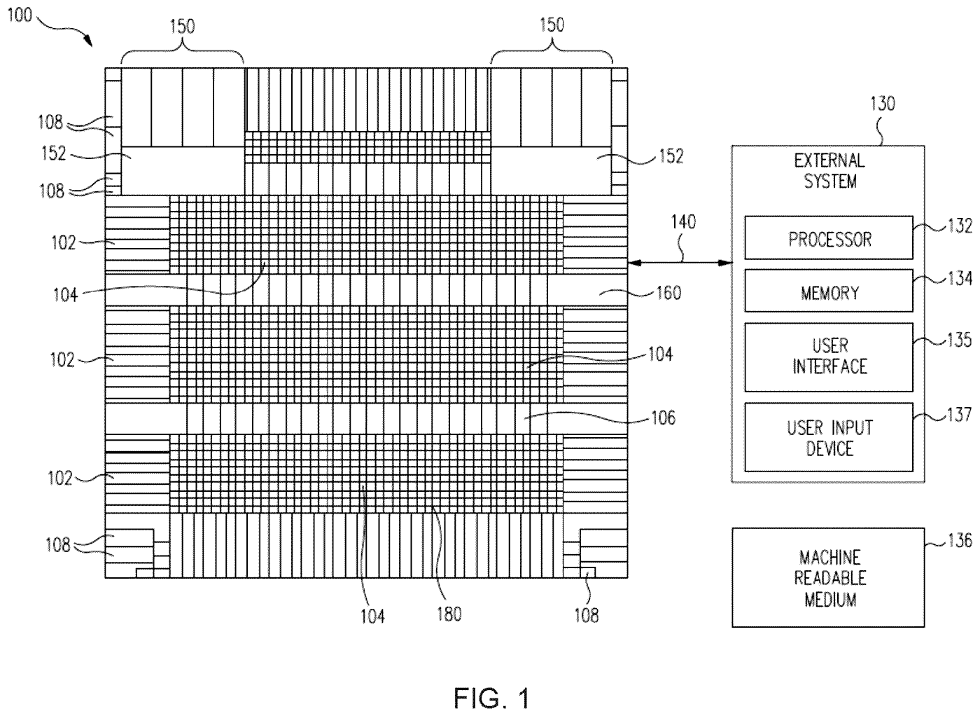

Referring now to the figures, FIG. 1 illustrates a block diagram of a PLD 100 in accordance with one or more embodiments of the present disclosure. In various embodiments, the PLD 100 may be implemented as a standalone device, for example, or may be embedded in a die that contains a system on a chip (SOC), other logic devices, and/or other integrated circuit(s). The PLD 100 (e.g., a field programmable gate array (FPGA), a complex programmable logic device (CPLD), a field programmable system on a chip (FPSC), or other type of programmable device) generally includes input/output (I/O) blocks 102 and logic blocks 104 (e.g., also referred to as programmable logic blocks (PLBs), programmable functional units (PFUs), or programmable logic cells (PLCs)). In some cases, the PLD 100 may generally be a_ny type of programmable device (e.g., programmable integrated circuit) with distributed configuration, which may involve loading configuration data through pins, shifting to appropriate locations in associated fabric, and configuring configuration memory cells. The PLBs may also be referred to as logic blocks, programmable functional units (PFUs), or programmable logic cells (PLCs). In an aspect, the PLBs 104 may collectively form an integrated circuit (IC) core or logic core of the PLD 100. The I/O blocks 102 provide I/O functionality (e.g., to support one or more I/O and/or memory interface standards) for the PLD 100, while the PLBs 104 provide logic functionality (e.g., LDT-based logic) for the PLD 100. Additional I/O functionality may be provided by serializer/deserializer (SERDES) blocks 150 and physical coding sublayer (PCS) blocks 152. The PLD 100 may also include hard intellectual property core (IP) blocks 160 to provide additional functionality (e.g., substantially predetermined functionality provided in hardware which may be configured with less programming than the PLBs 104).

The PLD 100 may include blocks of memory 106 (e.g., blocks of erasable programmable read-only memory (EEPROM), block static RAM (SRAM), and/or flash memory), clock-related circuitry 108 (e.g., clock sources, phase-locked loop (PLL) circuits, delay-locked loop (DLL) circuits, and/or feedline interconnects), and/or various routing resources 180 (e.g., interconnect and appropriate switching circuits to provide paths for routing signals throughout the PLD 100, such as for clock signals, data signals, control signals, or others) as appropriate. In general, the various elements of the PLD 100 may be used to perform their intended functions for desired applications, as would be understood by one skilled in the art.

For example, certain of the I/O blocks 102 may be used for programming the memory 106 or transferring information (e.g., various types of user data and/or control signals) to/from the PLD 100. Other of the I/O blocks 102 include a first programming port (which may represent a central processing unit (CPU) port, a peripheral data port, a serial peripheral interface (SPI) interface, and/or a sysCONFIG programming port) and/or a second programming port such as a joint test action group (JTAG) port (e.g., by employing standards such as Institute of Electrical and Electronics Engineers (IEEE) 1149.1 or 1532 standards). In various embodiments, the I/O blocks 102 may be included to receive configuration data and commands (e.g., over one or more connections) to configure the PLD 100 for its intended use and to support serial or parallel device configuration and information transfer with the SERDES blocks 150, PCS blocks 152, hard IP blocks 160, and/or PLBs 104 as appropriate. In another example, the routing resources 180 may be used to route connections between components, such as between I/O nodes of logic blocks 104. In some embodiments, such routing resources may include programmable elements (e.g., nodes where multiple routing resources intersect) that may be used to selectively form a signal path for a particular connection between components of the PLD 100.

It should be understood that the number and placement of the various elements are not limiting and may depend upon the desired application. For example, various elements may not be required for a desired application or design specification (e.g., for the type of programmable device selected). Furthermore, it should be understood that the elements are illustrated in block form for clarity and that various elements would typically be distributed throughout the PLD 100, such as in and between the PLBs 104, hard IP blocks 160, and routing resources 180 to perform their conventional functions (e.g., storing configuration data that configures the PLD 100 or providing interconnect structure within the PLD 100). For example, the routing resources 180 may be used for internal connections within each PLB 104 and/or between different PLBs 104. It should also be understood that the various embodiments disclosed herein are not limited to programmable logic devices, such as the PLD 100, and may be applied to various other types of programmable devices, as would be understood by one skilled in the art.

An external system 130 may be used to create a desired user configuration or design of the PLD 100 and generate corresponding configuration data to program (e.g., configure) the PLD 100. For example, to configure the PLD 100, the system 130 may provide such configuration data to one or more of the I/O blocks 102, PLBs 104, SERDES blocks 150, and/or other portions of the PLD 100. In this regard, the external system 130 may include a link 140 that connects to a programming port (e.g., SPI, JTAG) of the PLD 100 to facilitate transfer of the configuration data from the external system 130 to the PLD 100. As a result, the I/O blocks 102, PLBs 104, various of the routing resources 180, and any other appropriate components of the PLD 100 may be configured to operate in accordance with user-specified applications.

In the illustrated embodiment, the system 130 is implemented as a computer system. In this regard, the system 130 includes, for example, one or more processors 132 that may be configured to execute instructions, such as software instructions, provided in one or more memories 134 and/or stored in non-transitory form in one or more non-transitory machine readable media 136 (e.g., which may be internal or external to the system 130). For example, in some embodiments, the system 130 may run PLD configuration software, such as Lattice Diamond System Planner software available from Lattice Semiconductor Corporation to permit a user to create a desired configuration and generate corresponding configuration data to program the PLD 100. In this regard, in some cases, the system 130 and/or other external/remote system may be used for factory programming or remote programming (e.g., remote updating) of one or more PLDs (e.g., through a network), such as the PLD 100.

The configuration data may alternatively or in addition be stored on the PLD 100 (e.g., stored in a memory located within the PLD 100) and/or a separate/discrete memory of a system including the PLD 100 and the separate/discrete memory (e.g., a system within which the PLD 100 is operating). In some embodiments, the memory 106 of the PLD 100 may include non-volatile memory (e.g., flash memory) utilized to store the configuration data generated and provided to the memory 106 by the external system 130. During configuration of the PLD 100, the non-volatile memory may provide the configuration data via configuration paths and associated data lines to configure the various portions (e.g., I/O blocks 102, PLBs 104, SERDES blocks 150, routing resources 180, and/or other portions) of the PLD 100. In some cases, the configuration data may be stored in non-volatile memory external to the PLD 100 (e.g., on an external hard drive such as the memories 134 in the system 130). During configuration, the configuration data may be provided (e.g., loaded) from the external non-volatile memory into the PLD 100 to configure the PLD 100.

The system 130 also includes, for example, a user interface 135 (e.g., a screen or display) to display information to a user, and one or more user input devices 137 (e.g., a keyboard, mouse, trackball, touchscreen, and/or other device) to receive user commands or design entry to prepare a desired configuration of the PLD 100. In some embodiments, user interface 135 may be adapted to display a netlist, a component placement, a connection routing, hardware description language (HDL) code, and/or other final and/or intermediary representations of a desired circuit design, for example.

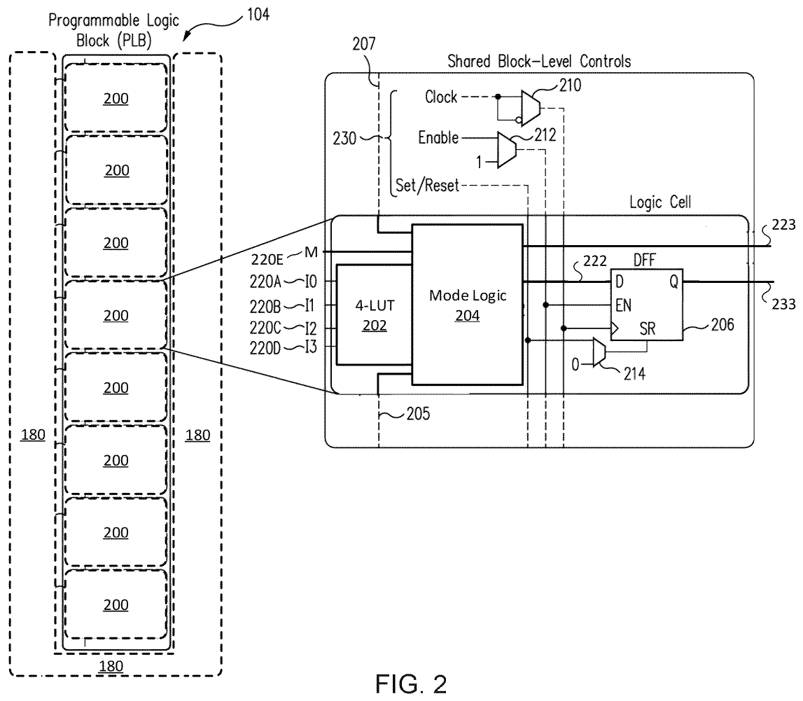

FIG. 2 illustrates a block diagram of a logic block 104 of the PLD 100 in accordance with one or more embodiments of the present disclosure. As discussed, the PLD 100 includes a plurality of logic blocks 104 including various components to provide logic and arithmetic functionality. In the example embodiment shown in FIG. 2, the logic block 104 includes a plurality of logic cells 200, which may be interconnected internally within logic block 104 and/or externally using the routing resources 180. For example, each logic cell 200 may include various components such as: a lookup table (LUT) 202, a mode logic circuit 204, a register 206 (e.g., a flip-flop or latch), and various programmable multiplexers (e.g., programmable multiplexers 212 and 214) for selecting desired signal paths for the logic cell 200 and/or between logic cells 200. In this example, the LUT 202 accepts four inputs 220A-220D, which makes it a four-input LUT (which may be abbreviated as “4-LUT” or “LUT4”) that can be programmed by configuration data for the PLD 100 to implement any appropriate logic operation having four inputs or less.

The mode logic 204 may include various logic elements and/or additional inputs, such as an input 220E, to support the functionality of various modes for the logic cell 200 (e.g., including various processing and/or functionality modes). The LUT 202 in other examples may be of any other suitable size having any other suitable number of inputs for a particular implementation of a PLD. In some embodiments, different size LUTs may be provided for different logic blocks 104 and/or different logic cells 200.

An output signal 222 from the LUT 202 and/or the mode logic 204 may in some embodiments be passed through the register 206 to provide an output signal 233 of the logic cell 200. In various embodiments, an output signal 223 from the LUT 202 and/or the mode logic 204 may be passed to the output 223 directly, as shown. Depending on the configuration of multiplexers 210-214 and/or the mode logic 204, the output signal 222 may be temporarily stored (e.g., latched) in the register 206 according to control signals 230. In some embodiments, configuration data for the PLD 100 may configure the output 223 and/or 233 of the logic cell 200 to be provided as one or more inputs of another logic cell 200 (e.g., in another logic block or the same logic block) in a staged or cascaded arrangement (e.g., comprising multiple levels) to configure logic and/or other operations that cannot be implemented in a single logic cell 200 (e.g., operations that have too many inputs to be implemented by a single LUT 202). Moreover, logic cells 200 may be implemented with multiple outputs and/or interconnections to facilitate selectable modes of operation.

The mode logic circuit 204 may be utilized for some configurations of the PLD 100 to efficiently implement arithmetic operations such as adders, subtractors, comparators, counters, or other operations, to efficiently form some extended logic operations (e.g., higher order LUTs, working on multiple bit data), to efficiently implement a relatively small RAM, and/or to allow for selection between logic, arithmetic, extended logic, and/or other selectable modes of operation. In this regard, the mode logic circuits 204, across multiple logic cells 202, may be chained together to pass carry-in signals 205 and carry-out signals 207, and/or other signals (e.g., output signals 222) between adjacent logic cells 202. In the example of FIG. 2, the carry-in signal 205 may be passed directly to the mode logic circuit 204, for example, or may be passed to the mode logic circuit 204 by configuring one or more programmable multiplexers. In some cases, the mode logic circuits 204 may be chained across multiple logic blocks I 04.

The logic cell 200 illustrated in FIG. 2 is merely an example, and logic cells 200 according to different embodiments may include different combinations and arrangements of PLD components. Also, although FIG. 2 illustrates a logic block 104 having eight logic cells 200, a logic block 104 according to other embodiments may include fewer logic cells 200 or more logic cells 200. Each of the logic cells 200 of a logic block 104 may be used to implem nt a portion of a user design implemented by the PLD I 00. In this regard, the PLD I 00 may include many logic blocks I 04, each of which may include logic cells 200 and/or other components which are used to collectively implement the user design.

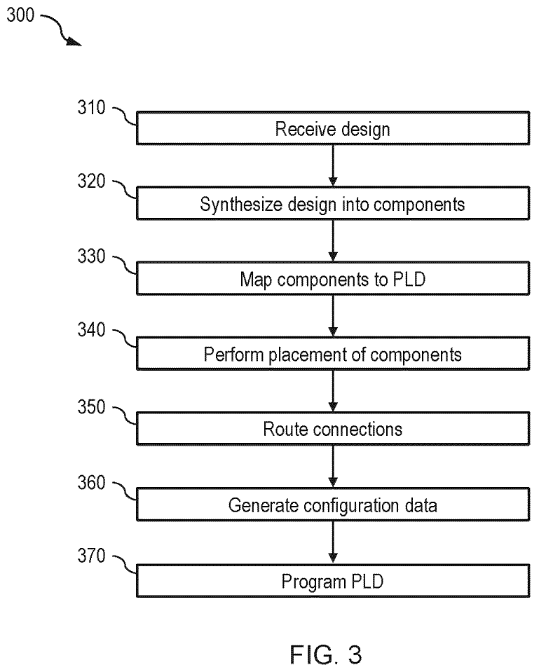

FIG. 3 illustrates a design process 300 for a PLD in accordance with one or more embodiments of the present disclosure. For example, the process of FIG. 3 may be performed by system 130 running Lattice Diamond software to configure the PLD 100. In some embodiments, the various files and information referenced in FIG. 3 may be stored, for example, in one or more databases and/or other data structures in the memory 134, the machine readable medium 136, and/or other storage.

In operation 310, the system 130 receives a user design that specifies the desired functionality of the PLD 100. For example, the user may interact with the system 130 (e.g., through the user input device 137 and HDL code representing the design) to identify various features of the user design (e.g., high level logic operations, hardware configurations, I/O and/or SERDES operations, and/or other features). In some embodiments, the user design may be provided in a register transfer level (RTL) description (e.g., a gate level description). The system 130 may perform one or more rule checks to confirm that the user design describes a valid configuration of PLD 100. For example, the system 130 may reject invalid configurations and/or request the user to provide new design information as appropriate. In an embodiment, each logic instance (e.g., implemented on a PLD) may receive a respective user design.

In operation 320, the system 130 synthesizes the design to create a netlist (e.g., a synthesized RTL description) identifying an abstract logic implementation of the user design as a plurality of logic components (e.g., also referred to as netlist components). In some embodiments, the netlist may be stored in Electronic Design Interchange Format (EDIF) in a Native Generic Database (NGD) file.

In some embodiments, synthesizing the design into a netlist in operation 320 may involve converting (e.g., translating) the high-level description of logic operations, hardware configurations, and/or other features in the user design into a set of PLD components (e.g., logic blocks 104, logic cells 200, and other components of the PLD 100 configured for logic, arithmetic, or other hardware functions to implement the user design) and their associated interconnections or signals. Depending on embodiments, the converted user design may be represented as a netlist.

In some embodiments, synthesizing the design into a netlist in operation 320 may further involve performing an optimization process on the user design (e.g., the user design converted/translated into a set of PLD components and their associated interconnections or signals) to reduce propagation delays, consumption of PLD resources and routing resources, and/or otherwise optimize the performance of the PLD when configured to implement the user design. Depending on embodiments, the optimization process may be performed on a netlist representing the converted/translated user design. Depending on embodiments, the optimization process may represent the optimized user design in a netlist (e.g., to produce an optimized netlist).

In some embodiments, the optimization process may include optimizing routing connections identified in a user design. For example, the optimization process may include detecting connections with timing errors in the user design, and interchanging and/or adjusting PLD resources implementing the invalid connections and/or other connections to reduce the number of PLD components and/or routing resources used to implement the connections and/or to reduce the propagation delay associated with the connections. In some cases, wiring distances may be determined based on timing.

In operation 330, the system 130 performs a mapping process that identifies components of the PLD 100 that may be used to implement the user design. In this regard, the system 130 may map the optimized netlist (e.g., stored in operation 320 as a result of the optimization process) to various types of components provided by the PLD 100 (e.g., logic blocks 104, logic cells 200, embedded hardware, and/or other portions of the PLD 100) and their associated signals (e.g., in a logical fashion, but without yet specifying placement or routing). In some embodiments, the mapping may be performed on one or more previously-stored NGD files, with the mapping results stored as a physical design file (e.g., also referred to as an NCD file). In some embodiments, the mapping process may be performed as part of the synthesis process in operation 320 to produce a netlist that is mapped to PLD components.

In operation 340, the system 130 performs a placement process to assign the mapped netlist components to particular physical components residing at specific physical locations of the PLD 100 (e.g., assigned to particular logic cells 200, logic blocks 104, clock-related circuitry 108, routing resources 180, and/or other physical components of PLD 100), and thus determine a layout for the PLD 100. In some embodiments, the placement may be performed in memory on data retrieved from one or more previously-stored NCD files, for example, and/or on one or more previously-stored NCD files, with the placement results stored (e.g., in the memory 134 and/or the machine readable medium 136) as another physical design file.

In operation 350, the system 130 performs a routing process to route connections (e.g., using the routing resources 180) among the components of the PLD 100 based on the placement layout determined in operation 340 to realize the physical interconnections among the placed components. In some embodiments, the routing may be performed in memory on data retrieved from one or more previously-stored NCD files, for example, and/or on one or more previously-stored NCD files, with the routing results stored (e.g., in the memory 134 and/or the machine readable medium 136) as another physical design file.

In various embodiments, routing the connections in operation 350 may further involve performing an optimization process on the user design to reduce propagation delays, consumption of PLD resources and/or routing resources, and/or otherwise optimize the performance of the PLD when configured to implement the user design. The optimization process may in some embodiments be performed on a physical design file representing the converted/translated user design, and the optimization process may represent the optimized user design in the physical design file (e.g., to produce an optimized physical design file).

Changes in the routing may be propagated back to prior operations, such as synthesis, mapping, and/or placement, to further optimize various aspects of the user design.

Thus, following operation 350, one or more physical design files may be provided which specify the user design after it has been synthesized (e.g., converted and optimized), mapped, placed, and routed (e.g., further optimized) for the PLD 100 (e.g., by combining the results of the corresponding previous operations). In operation 360, the system 130 generates configuration data for the synthesized, mapped, placed, and routed user design. In various embodiments, such configuration data may be encrypted and/or otherwise secured as part of such generation process. In operation 370, the system 130 configures/programs the PLD 100 with the configuration data (e.g., a configuration) into the PLD 100 over the connection 140. Such configuration may be provided in an encrypted, signed, or unsecured/unauthenticated form dependent on application/requirements.

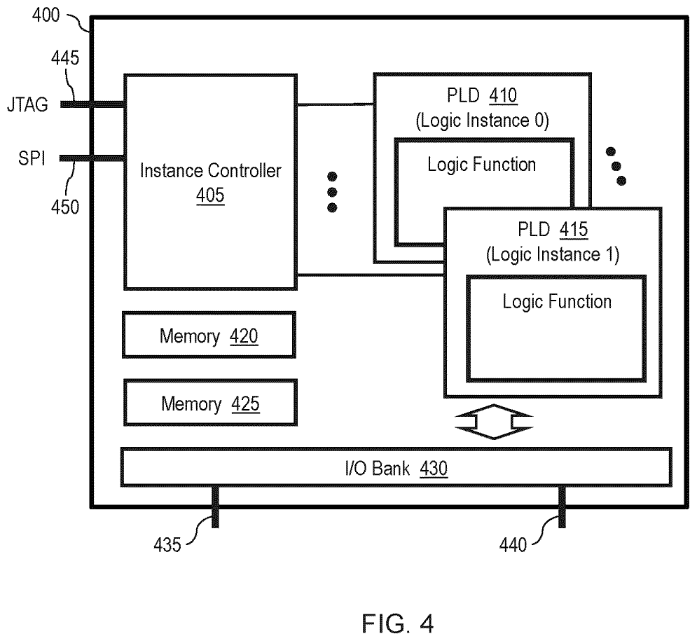

FIG. 4 illustrates an example context switch device/architecture 400 in accordance with one or more embodiments of the present disclosure. The context switch device 400 includes an instance controller 405, PLDs 410 and 415, memories 420 and 425, and an I/O bank 430. In some embodiments, the context switch device 400 may be implemented as a multi-chip system. For example, the instance controller 405, the PLD 410, and the PLD 415 may be on separate chips. The multi-chip system may also be referred to as a multi-die system, multi-die module system, or multi-die module. In an aspect, the instance controller 405 may be referred to as a secure configuration engine and instance enable control or a secure configuration instance control (SCIC), and/or the PLDs 410 and 415 may be referred to as a logic instance 0 and N, respectively, or simply an instanceOand N, respectively, where N is the number of logic instances and N2::2. In an embodiment, each of the PLDs 410 and/or 415 may be, may include, may be a part of, and/or may be implemented with an architecture/components similar to or the same as the PLD 100.

Ellipses between the PLDs 410 and 415 indicate that one or more additional PLDs (e.g., additional logic instances) are present between the PLDs 410 and 415 (e.g., the context switch device 400 has more than two logic instances) or no PLDs are present the PLDs 410 and 415. In this regard, for explanatory purposes, the context switch device 400 includes N=2 logic instances, although in other embodiments the context switch device 400 may include more than two logic instances. As such, for explanatory purposes, the PLD 410 may also be referred to as instance 0 and the PLD 415 may also be referred to as instance 1.

The context switch device 400 includes various connections between the instance controller 405 and each of the PLDs 410 and 415 as well as various connections to/from outside the context switch device 400. It is noted that the context switch device 400 as shown in FIG. 4 may not explicitly depict all connections between components of the context switch device 400 and connections to/from devices external to the context switch device 400.

The instance controller 405 manages configuration of each logic instance (e.g., the PLDs 405 and 410), determines and sets which instance is currently active and which instance(s) is currently inactive, and manages context switching (e.g., also referred to as a switchover). In some aspects, the instance controller 405 is or includes a hard IP block, in which its functionality is fixed and cannot be modified by a user of the context switch device 400. In some cases, even when the instance controller 405 is a hard IP block, the instance controller 405 may have parameters that may be set by the user.

Each of the PLDs 410 and 415 may be configured using configuration data to perform logic functions. In some aspects, at least a portion of the logic function may include a security monitoring function. Each of the PLDs 410 and 415 may be associated with a logic instance number. For example, as provided above, the PLD 410 may be associated with a logic instance number of 0 and the PLD 415 may be associated with a logic instance number of 1. In this example, the PLD 410 may be referred to as logic instance 0 or simply instance 0 and the PLD 415 may be referred to as logic instance 1 or simply instance 1. In an aspect, each logic instance has an instance identification pin used to identify its logic instance number. In the case with two instances, as in the context switch device 400, the PLD 410 may have an instance identification pin that is driven low (e.g., logic 0) and the PLD 415 may have an instance identification pin that is driven high (e.g., logic 1).

Each of the PLDs 410 and 415 have its own separate configuration block (denoted as CFG or Config). In some aspects, the context switching device 400 has a single manager serial peripheral interface (MSPI) port. A boot control block may activate only one CFG per context switching function and a multiplexing function may connect only one CFG to the MSPI port at a context switching package level. Supported configuration paths include MSPI and subordinate serial peripheral interface (SSPI). For MSPI, the context switch device 405 reads contents (e.g., including configuration data) from an external memory (e.g., an external flash device). For SSPI, an external system controller writes configuration data (e.g., configuration bitstream) to the context switch device 405. The SSPI configures one instance at a time with the configuration bitstream (e.g., the user's configuration bitstream). The context switch device 400 may have finite state machines (FSMs) controlling the MSPI port per a context switch controller's request.

The PLDs 410 and 415 may have some functionality provided by a manufacturer of the PLDs 410 and 415. The user may design their own logic with certain constraints. In an aspect, one constraint is that the instance controller 405 cannot change which instance is the active instance at an arbitrary time/state since context switching may break operation in the middle (e.g., image recovery). In this regard, when the active instance is running the user function, the active instance is not switched to an inactive instance at an arbitrary time/state as such a switch may break operation in a middle or an unstable state (e.g., image recovery). In some cases, to satisfy this constraint, switching to a new active instance can occur only at a state that is safe/stable to change, as further described herein. Such a state for an instance may be referred to as a ready to change (R2C) state. In some aspects, each logic instance listens before being fully enabled and has to lock their PLLs and stabilize its logic prior to becoming active. Only one instance at a time can become active. Once conditions for becoming active are correct/met, a context switch (e.g., nearly instantaneous context switch) may be performed from one logic instance to another logic instance.

Certain conditions may govern entry to the R2C state. In some aspects, for the active instance, the active instance can enter the R2C state when the active instance does not have any ongoing active interaction with system blocks outside of the instance. Any current interactions are to be finished in a normal way before the active instance enters the R2C state. If possible, there should be fixed values at the shared output I/Os in the R2C state. Having fixed values prevents a change of active instances from disturbing I/Os. Various context switching techniques herein support a smooth transition of I/O even if they are different in the R2C state. In some aspects, a request to go to the R2C state may come as an interrupt (INTR) to the user logic design.

In some aspects, the PLDs 410 and 415 may detect a change of active instance by monitoring an active signal from the instance controller 405. In some cases, the PLDs 410 and 415 may monitor a synchronized version of the active signal denoted as active_sync. The instance with active_sync==0−−−−−+1 (e.g., transitioned to the active mode) starts the normal operation with driving I/Os. The instance with active_sync==1 −−−−−+0 (e.g., transitioned to the inactive mode) may stay in the R2C state and/or keep running in listen mode.

In some embodiments, the logic instances (e.g., the PLDs 410 and 415) may share an external I/O with only one instance being active at a time. A state (e.g., active or inactive) of each logic instance is controlled by the instance controller 405. Each inactive instance is in a listen mode after it is configured. Each instance may have multiple connections to the instance controller 405 that handles the inter-chip communication (ICC), boot control, JTAG and SSPI functions, and expanded I/O (EIO). The instances may get configured/updated via JTAG/SSPI or by an external flash via MSPI. Configuration of the instances is controlled by theinstance controller 405. It is noted that clocks of the instance controller 405 and the instances are frequency locked but may have different clock phases (e.g., not a synchronous system).

The memories 420 and 425 are memories shared by the logic instances (e.g., the PLD 410,415, and others if any not explicitly shown in FIG. 4). The memories 420 and 425 may be used to store data for facilitating synchronization of two or more instances when contex switching. The memory 420 may be a user flash memory (UFM). In some embodiments, the memory 420 may be protected from live update failure. Stored data (e.g., UFM data) such as boot up sequence bits may be allowed to be updated by the active instance via a live update. This live update may be different from an initial program of the memory 420 in the factory in that the live update may fail due to various reasons including power failure. To avoid failure of the live update, multiple copies of information may be used with corresponding valid bits.

The memory 425 may be a shared static random-access memory (SRAM). The memory 425 may be an embedded block RAM (EBR). In some cases, the memory 425 may have less storage space than the memory 420. Although in FIG. 4 the memories 420 and 425 are external to the instance controller 405, in some cases the memory 420 and/or the memory 425 may be part of the instance controller 405.

The I/O bank 430 may include hundreds of I/Os (e.g., programmable I/Os) shared by the instances (e.g., the PLDs 410 and 415). The I/O bank 430 is coupled to interfaces 435 and 440. The interfaces 435 may include SPI and other interface security monitors. The interfaces 440 may include interfaces for receiving other control signals. In an aspect, a first subset of I/Os (e.g., pins) of the I/O bank 430 may be directly controlled by an active PLD (e.g., an active instance) and a second subset of the programmable I/Os 410 may be controlled via an I/O expander bus. The first subset of I/Os (e.g., pins) may be low-latency I/O. At any one time, only one instance can actively drive the I/O to prevent any contention. These I/O may be directly controlled by user logic in each instance. The first subset of I/Os are to be handled appropriately to facilitate successful context switching (e.g., switching from driving the first subset of I/Os using one instance to driving the second subset of I/Os using another instance). In some cases, the first subset of I/Os may be referred to as shared I/Os (e.g., shared by the instances although with only the active instance having write access to these I/Os). As one non-limiting example, the programmable I/Os 410 may support low voltage complementary metal-oxide-semiconductor (LVCMOS) 1.0 V to 3.3 V, although other technologies and/or other voltages may be used.

In some embodiments, the context switch device 400 may be used for facilitating platform firmware resiliency (PFR). During the R2C state, the active instance may have no-ongoing tasks except possibly a listen mode to monitor SPI access. A system that includes the context switching device 400 performs operations as needed to facilitate platform firmware resiliency including recovery of contaminated firmware using roll back, detection of contaminated firmware by accessing outside flash, and/or protection of SPI memory access by monitoring the address space of access.

In some embodiments, the communication of a request for an instance to enter the R2C state (e.g., denoted as res_request) and a notification of an instance reaching the R2C state (e.g., denoted as rcs_ready) may be done over level sensitive asynchronous wires. As an example, the res_request may become the interrupt to the user logic in the PLDs 410 and 415 through an associated interrupt controller. The rcs_ready may enter the instance controller 405 (e.g., its context switch controller) as an asynchronous signal. The inactive instance, once configured, may be in a continuous monitoring state in the case that the active instance has entered the R2C state. The inactive instance may perform certain functions, such as logging an external event. As an example, when an instance provides PFR functionality, in the R2C state, an instance may perform protection (e.g., monitoring and internal operation) while not being able to perform detection or recovery (e.g., driving pins and interaction with outside components). The protection can put a log for PFR CPU (FSM) to check and react later. Once context switching transitions the inactive instance to a current active instance, the now current active instance may then communicate this external event to the rest of the system to avoid missing events.

If the I/O output values during the R2C state of both instances are the same and static, a safe transition of I/O ownership may be possible even without sophisticated mechanisms. An output driver of the new active instance may be turned on, and then an output driver of the current active instance (e.g., new inactive instance) turned off. A delay between turning on the new active instance's output driver and the current active instance's output driver is greater than a wire delay difference of driver signals (e.g., the active signals). An output signal driver buffer in both instances are controlled by the active signals coming from the instance controller 405 directly without any synchronization. Such transfer may prevent any period in which no instance drives the I/Os. Simultaneous driving of the I/Os can occur since the output values are the same.

If the I/O output values during the R2C state of both instances are static but different, then a hold enabled I/O may be used to prevent any short pulse during the switchover from one instance to the other instance. The instance controller 405 may intentionally overlap the active signals associated with the PLDs 410 and 415 for one cycle and at an interrupt does a triple synchronization of the active signals. The one cycle overlap removes any period in which no one instance drives the I/Os. For example, a sample and hold circuit may make the two instances drive the same value in the overlap time. The delay between the triple synced active at each instance and active at the instance controller 405 ensures the greater than one cycle hold time and prevents any short pulse (e.g., signal stretching).

Various context switching functions of the instance controller 405 may communicate via various methods including, by way of non-limiting examples, advanced high-performance bus-lite (AHB-L), EIO, JTAG/SSPI multiplexing, and manager SPI (MSPI). The instance controller 405 includes JTAG interfaces 445 and an SSPI interfaces 450. The JTAG interfaces 445 and the SSPI interfaces 450 may be used for configuring the PLDs 410 and 415. The instance controller 405 may include other interfaces such as I3C and control and status interfaces.

The SSPI interfaces 440 may support the configuration SSPI of the instances (e.g., the PLDs 410 and 415) and the control SSPI in the instance controller 405. Signals may be used to select one instance at a time. In some aspects, only one of these signals can be driven active at a time, otherwise behavior of the context switch device 400 is undefined. The PLDs 410 and 415 may use the same pins (e.g., shared pins) between the JTAG and SSPI ports. In conventional non-context-switch cases, if a PLD was standalone on a printed circuit board, the user would hardwire the selection to either JTAG or SSPI per system requirements. In the case of context switching, the JTAG/SSPI port usage may not be known beforehand. As such, in some embodiments, the instance controller 405 includes a bidirectional multiplexer (mux) to provide a multiplexing function for supporting both JTAG and SSPI connections external to the context switch device 400. For this bidirectional multiplexer, an external JTAG enable signal (e.g., denoted as JTAG_EN signal) may be used to select between JTAG or SSPI. As an example, the JTAG enable signal may be set to 1 (e.g., logic high) to select/enable JTAG and set to O (e.g., logic low) to select/enable SSPI.

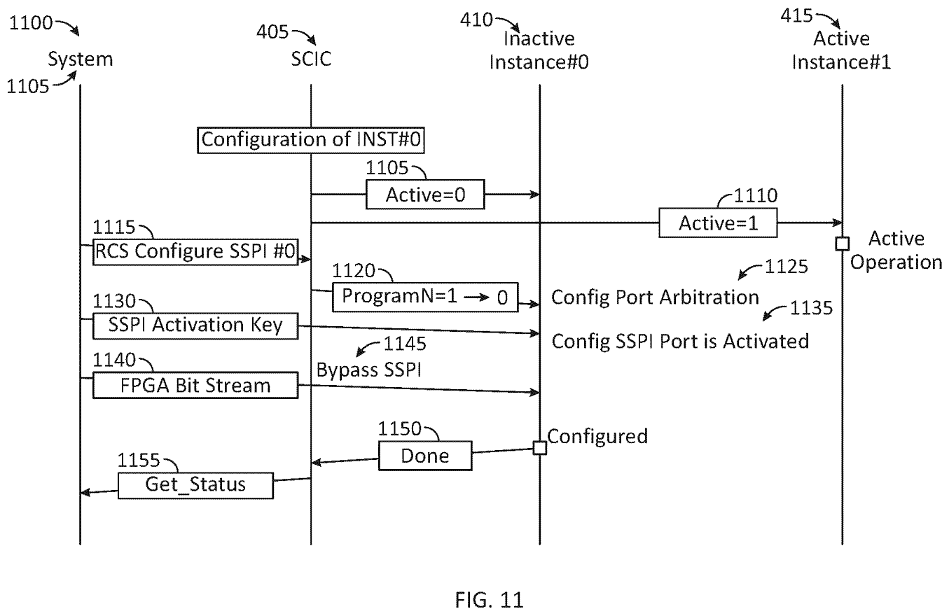

In some embodiments, configuration data (e.g., stored in CRAM) of each instance may be read out by an external system controller either by JTAG or SSPI. To read the CRAM via JTAG, the JTAG enable signal is enabled (e.g., set to 1). A CPU may send a command to JTAG to read the CRAM. An instance returns the CRAM contents and the CPU checks the contents. Examples of reading CRAM via SSPI are described at least with reference to FIG. 11.

The context switch device 400 may support ICC function. ICC function may be used to connect the instances (e.g., the PLDs 410 and 415) to resources in the instance controller 405 so that user logic in the instances may use resources such as I/Os, the memories 420 and 425, and/or other components of the instance controller 405. ICCs that involve the instance controller 405 may include an ICC-AHB-L and an ICC-EIO. ICC-AHB-L may connect the AHB-L bus in the instances to the instance controller 405. ICC-EIO may connect the expanded or virtual port of an instance user module of the I/O of the instance controller 405 to support the expanded I/O feature.

ICC may further include ICC transmit (TX) and ICC receive (RX) modules separate from modules for ICC-AHB-L and ICC-EIO. ICC may also provide for passing context information between two instances, such as passing information from the current active instance to the next active instance. For example, such passing of context information may be used to inform what events have already been handled or have not already been handled by the current active instance so that the next active instance performs the correct actions upon becoming active.

The context switch device 400 may also support ICC for direct (cross coupled) communications between two instances. In one case, the ICC may include cross-coupled 3-wire connection. A bitstream is assumed to be instance neutral, with RX connected to TX and vice versa. For example, a manager universal asynchronous receiver-transmitter (UART) may be assigned to the same pins in both instances. The user may choose a protocol among EIO, I2C, or UART.

The context switching device 400 may support EIO function. EIO may be a physical I/O (PIO) available on the instance controller 405 and whose values are controlled by the instances. The user logic of the active instance may use ICC-EIO to send I/O data that the active instance wants to drive over to the I/O in the instance controller 405. The sampled value at the input I/O of the instance controller 405 may return to both of the instances' user module port via ICC-EIO. In general, while only the active instance can drive the EIO, the active and inactive instances continuously listen to the EIO values. In some cases, the EIO is a relatively high latency and low bandwidth (BW) I/O.

Virtual I/O may be shared between logic instances and the instance controller 405 (ICC-EIO). Two ICC-EIOs may be between the instance controller 405 and the PLD 410 and two ICC-EIOs may be between the instance controller 405 and the PLD 415. Each ICC-EIO may use a first set of wires from an instance to the instance controller 405 and a second set of wires from the instance controller 405 to the instance. The first set may include the same number of wires as the second set. An EIO to PIO mapping in the instance controller 405 may be a pre-defined mapping.

PIO values in the instance controller 405 should not be disturbed during active instance change. In some cases, to avoid disturbance to the PIO values, both instances are in the same R2C state where outputs are the same, including the expanded I/Os. As such, the change happens between the same values, thus having no distance. Since ICC-EIO works independently from the active instance selection, ICC-EIO may be in the middle of ICC_EIO communication.

A shadow register loading in the instance controller 405 may be reset and discard the loaded registers. It stops the PIO update. The shadow registers may be reloaded using the ICC-EIO from the newly activated instance. After that, the PIO update resumes. An instance stops use of output ICC-EIO as soon as the instance loses the activation (e.g., becomes an inactive instance). The instance controller 405 may reset the ICC-EIO buffer per an activation signal.

The EIO may support a background listen mode. In general, each instance traverses through a set of states, in order: configuration state, wait state, active state, stay at R2C state, inactive state, wait state, configuration state, and so forth. In the wait state, the instance may be used to monitor some I/Os in the background to allow for continuous monitoring and protection functionality. If monitoring is needed for the expanded I/O of the instance controller 405, an input ICC-EIO needs to keep sending the value of the EIOs to the instance. If monitoring is only for the instance's physical I/O, the input to the ICC-EIO channel entering the instance can be shut down.

As indicated above, the instance controller 405 controls configuration of the context switch device 400. During configuration, the instance controller 405 transfers the configuration data for the instances (e.g., the PLDs 410 and 415) based on boot sequence control signals (e.g., boot sequence control bits). The boot sequence control signals may define a boot up procedure for the instances (e.g., which instances to configure, configure and activate, or not configure and thus not activate). The boot sequence control signals may have a target instance identifier to identify an instance (e.g., identifier set to 0 to identify the PLD 410) and a boot mode set to a value indicating a mode of the PLD 410 and/or 415, as further described herein.

Configuration MSPI ports may be used to fetch an instance's configuration data from an external memory device (e.g., external flash device). In some cases, the configuration data may be default/golden configuration data. The boot up sequence control (e.g., located in the boot control block) may use bits in the UFM (e.g., the memory 420) of and/or coupled to the instance controller 405. The bits may include a target instance. For example, with two instances, two bits may be used to identify the instances with one bit associated with each instance. A single bit may be used to identify a boot mode. A 0 value for the boot mode may be used to set a mode in which only a target instance is configured and activated. A 1 value for the boot mode may be used to set a mode in which an inactive instance is configured and an active instance is configured and then activated. If a target instance is indicated as being inactive as well as active, after boot up, no configuration or activation is performed. The instance controller 405 may wait for a context switching command after boot up.

In some embodiments, MSPI is only used at boot up. After boot up, the SSPI interface is used. For SSPI, a system controller/CPU (e.g., an external system controller/CPU) sends a context switching command to the control SSPI in the instance controller 405. The command has the instance number to indicate the instance to configure (e.g., based on the identifier pin for each instance). The instance controller 405 starts a configuration SSPI port arbitration step for the instance to be configured. The system controller/CPU enables the configuration SSPI port and programs the instance via SSPI. In some cases, JTAG may optionally be used for configuration of the instances (e.g., the PLDs 410 and 415). A total configuration time is a function of the configuration data/bitstream size.

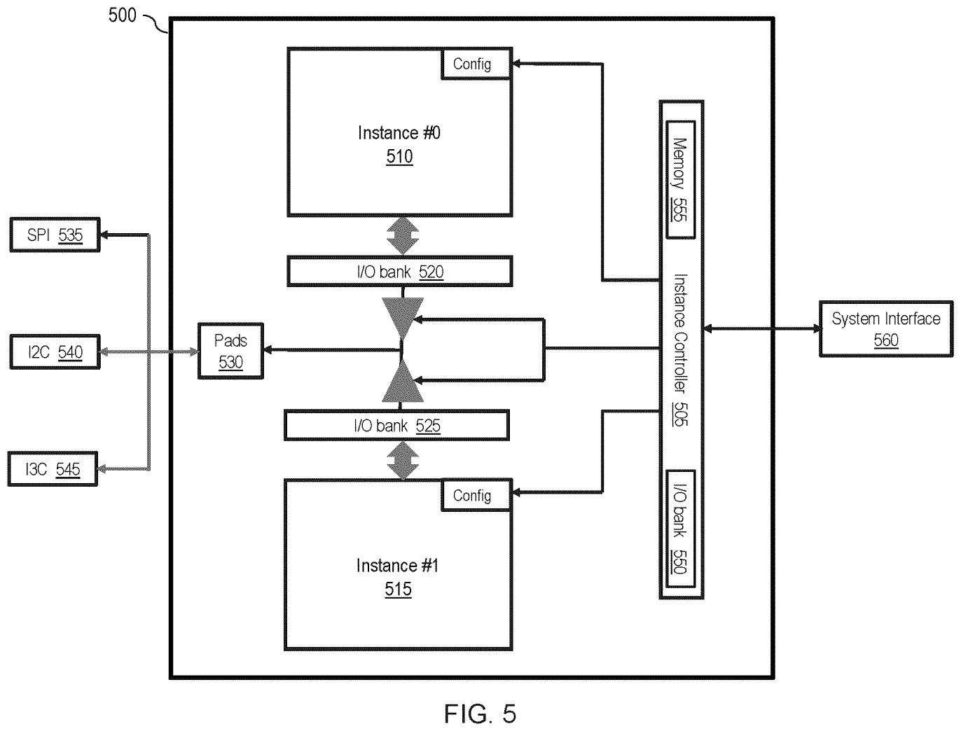

FIG. 5 illustrates another example context switch device/architecture 500 in accordance with one or more embodiments of the present disclosure. The description of the context switch device 400 of FIG. 4 generally applies to the context switch device 500 of FIG. 5, with examples of differences and other description provided herein. The context switch device 500 includes an instance controller 505, PLDs 510 and 515, I/O banks 520 and 525, and pads 530. In some embodiments, the context switch device 500 may be implemented as a multi-chip system. The PLDs 510 and 515 may be referred to as a logic instanceOand 1, respectively. In an embodiment, each of the PLDs 510 and/or 515 may be, may include, or may be a part of, the PLD 100. In an embodiment, the PLDs 510 and 515 may be operated in lockstep. In such an embodiment, the PLD 510 may be used as an active region and the PLD 515 may be used as a backup region, or vice versa. Although the context switch device 500 includes two instances, a context switch device may be expanded to include more than two instances.

The instance controller 505 includes a shared I/O bank 550 and a shared memory 555. Among the instances, at least a subset of I/Os of the I/O bank 550 may be actively driven only by the active instance. The shared memory 555 may be used to store synchronization data for synchronization of instances for facilitating context switching. In some cases, the shared memory 555 may include a UFM and a SRAM (e.g., EBR). The instance controller 505 may communicate with a configuration block of the PLDs 510 and 515 to configure the PLDs 510 and 515, respectively. The instance controller 505 may have appropriate interfaces (e.g., SPI) for communicating with a system interface 560. The system interface 560 may be coupled to an external system (e.g., a system controller/CPU external to the context switch device 500). The I/O bank 520 is directly accessible by the PLD 510. The I/O bank 525 is directly accessibly by the PLD 515. The pads 530 facilitate communication with interfaces 535, 540, and 545 associated with SPI, I2C, and BC, respectively. The context switch device 500 may have numerous internal and external connections/interfaces including a multiplexed JTAG and SSPI for configuration, ICC and boot control, cross coupled connections between the instances, an active instance I/O, a virtual I/O, an external flash interface, and/or others.

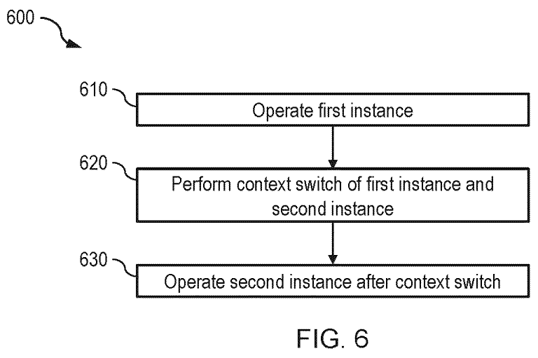

FIG. 6 illustrates a flow diagram of an example process 600 for context switching in accordance with one or more embodiments of the present disclosure. Although, for explanatory purposes, the process 600 is described with reference to systems, devices, processes, and elements of FIG. 4, the process 600 may be performed by other systems, devices, and elements, and including a different selection of electronic systems, devices, elements, assemblies, and/or arrangements. At the initiation of the process, various system parameters may be populated by prior execution of a process similar to the process, for example, or may be initialized to zero and/or one or more values corresponding to typical, stored, and/or learned values derived from past operation of the process. Note that one or more operations may be combined, omitted, and/or performed in a different order as desired.

For explanatory purposes, at a start of the process 600, the PLD 410 is the active instance and the PLD 415 is an inactive instance. In operation 610, the PLD 410 operates according to its configuration (e.g., its programmed user design) to provide its PLD functionality. In some aspects, as the active instance, the PLD 410 may be the only instance with write access to the shared 1/0 of the 1/0 bank 430. Prior to operation 610, the PLD 410 may be configured by the instance controller 405 using configuration data. In some cases, configuration of the PLD 410 may occur during boot up (e.g., via MSPI) or after boot up (e.g., via SSPI).

In operation 620, the instance controller 405 performs a context switch of the PLD 410 and the PLD 415. The context switch transitions the PLD 410 from the active state (e.g., the PLD 410 being the active instance) to the inactive state (e.g., the PLD 410 being an inactive instance) and transitions the PLD 415 from the inactive state to the active state. In some aspects, operations performed for the context switch and/or in preparation for the context switch may be performed by the instance controller 405, the PLD 410, the PLD 415, and/or other components, as further described herein. As an example, as the active instance, the PLD 410 may store data (e.g., synchronization data) associated with the context switch device 400 (e.g., components thereof) in the memories 420 and/or the 425 that the PLD 415 may load upon becoming the active instance to synchronize the PLD 415. Such synchronization may facilitate a seemless transition from operating the context switch device 400 with the PLD 410 as the active instance to operating the context switch device 400 with the PLD 415 as the active instance and allow for uninterrupted coverage of desired functionality.

In operation 630, the PLD 415 operates according to its configuration (e.g., its programmed user design). Configuration data used to configure the PLD 415 may be the same or different from configuration data used to configure the PLD 410. In an embodiment, for lockstep operation, the PLD 415 may be configured using the same configuration data as the PLD 410. For example, for lockstep operation, the PLD 410 may be taken offline to update its configuration (e.g., the PLD 410 will later become the active instance and the PLD 415 taken offline for a similar update), distribute use of the redundant instances, and/or for other reasons. In some aspects, as the new active instance, the PLD 415 may be the only instance with write access to the shared I/O of the I/O bank 430. Prior to operation 630, the PLD 415 may be configured by the instance controller 405 using configuration data. In some cases, configuration of the PLD 415 may occur during boot up (e.g., via MSPI) or after boot up (e.g., via SSPI).

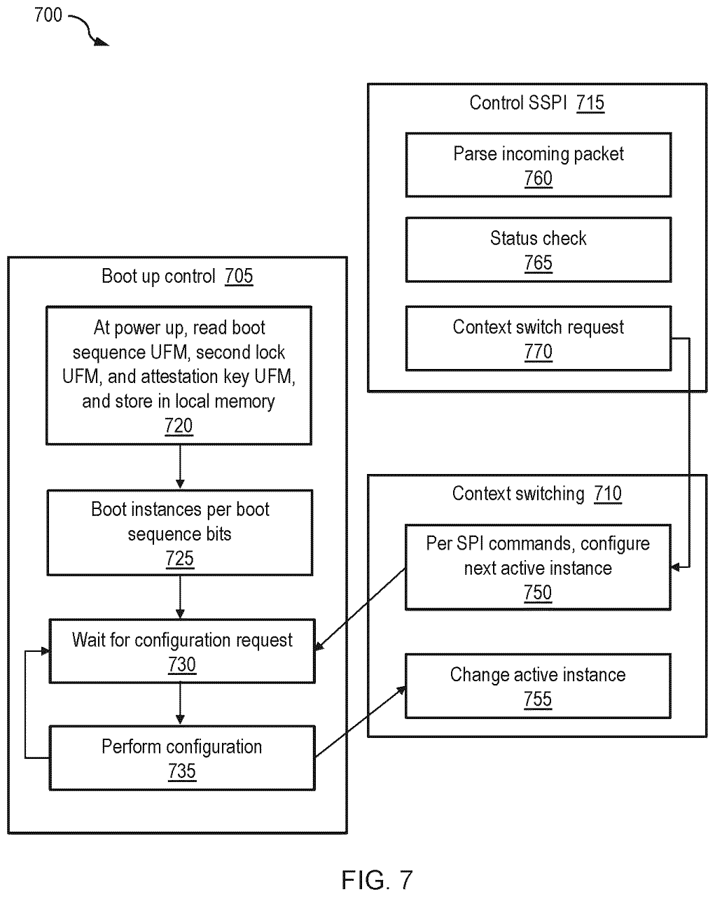

FIG. 7 illustrates a flow diagram of an example operation flow 700 for a context switch device (e.g., the context switch device 400 or 500) in accordance with one or more embodiments of the present disclosure. The operation flow 700 includes boot up control 705 (e.g., also referred to as boot control and implemented by a boot controller of the context switch device), context switching 710 (e.g., implemented by a context switch controller of the context switch device), and control SSPI 715 of the context switch device. Although, for explanatory purposes, the operation flow 700 is primarily described with reference to systems, devices, processes, and elements of FIG. 4, the operation flow 700 may be performed by other systems, devices, and elements, and including a different selection of electronic systems, devices, elements, assemblies, and/or arrangements.

In operation 720, the boot up controller of the instance controller 405, at power up, reads boot sequence UFM, second lock UFM, and attestation key UFM, and stores in local memory. In operation 725, the boot up controller boots instances according to boot sequence control bits. In operation 730, the boot up controller waits for a configuration request from the context switch controller to configure an instance.

In operation 760, the control SSPI 715 of the instance controller 405 parses an incoming packet(s). In operation 765, the control SSPI 715 performs status check of instances. In some cases, a get_status command may be used to obtain a status such as whether an instance is an active instance or an inactive instance, whether configuration of an instance is successful or not, whether context switching is successful or not, and/or others. In operation 770, the control SSPI 715 requests a context switch. In some cases, the control SSPI 715 may request the context switch in response to an incoming packet containing an instruction to the context switch device to initiate a context switch. In operation 750, the context switch controller, per SPI commands, configures a next active instance using the boot up control 705. In response to receiving a configuration request from the context switch controller, the operation 730 proceeds to operation 735. In operation 735, the boot controller performs configuration of the next active instance. Once the configuration is complete, the boot controller proceeds from operation 735 back to operation 730 to wait for another configuration request. In operation 755, the context switch controller changes the active instance upon successful configuration of the active instance after operation 735 is performed.

Configuration and activation at boot-up and after boot-up of instances may be controlled by context switch controller and boot controller functions of the instance controller 405. In some aspects, the instance controller 405 may include a context switch controller (e.g., also referred to as an RCS controller in some cases) for its context switch controller functions and a boot controller for its boot controller functions.

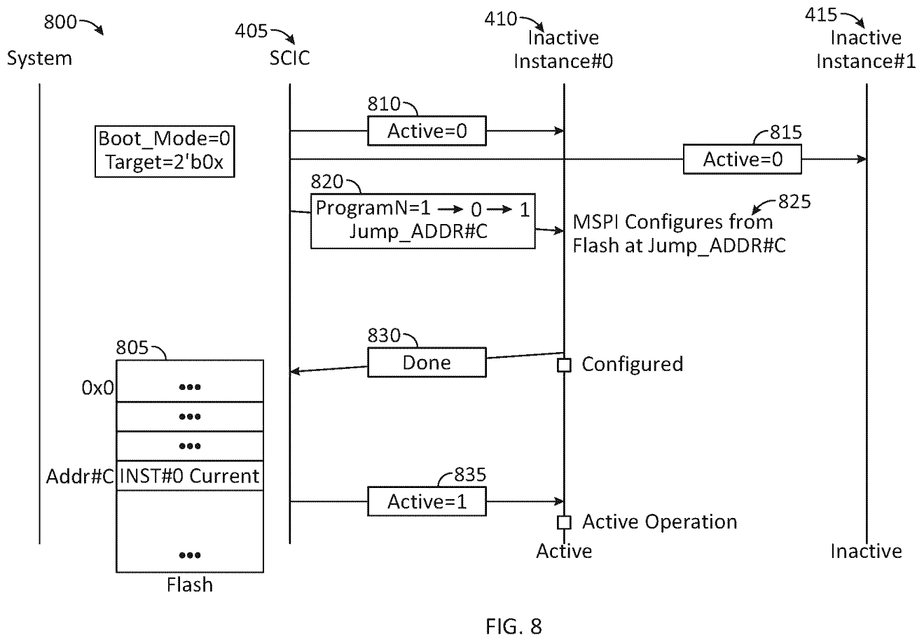

As an example boot up scenario, FIG. 8 illustrates a flow diagram of an example process 800 for configuration and activation during boot up in accordance with one or more embodiments of the present disclosure. Although, for explanatory purposes, the process 800 is described with reference to systems, devices, processes, and elements of FIG. 4, the process 800 may be performed by other systems, devices, and elements, and including a different selection of electronic systems, devices, elements, assemblies, and/or arrangements. At the initiation of the process, various system parameters may be populated by prior execution of a process similar to the process, for example, or may be initialized to zero and/or one or more values corresponding to typical, stored, and/or learned values derived from past operation of the process. Note that one or more operations may be combined, omitted, and/or performed in a different order as desired.

In operation 810, the instance controller 405 sets the PLD 410 to an inactive state, as shown by an active signal (e.g., an active flag) set to 0. In operation 815, the instance controller 405 initially sets the PLD 415 to an inactive state (e.g., also referred to as a non-active state), as shown by an active signal set to 0.

In operation 820, the instance controller 405 (e.g., the boot controller of the instance controller 405) transmits one or more control signals to cause configuration of the PLD 410. In some aspects, the instance controller 405 uses an MSPI configuration of a configuration block of the PLD 410 (e.g., the target instance) per boot sequence control bits. For performing operation 820, the boot sequence control bits may have a target instance identifier set to 0 to identify the PLD 410 and a boot mode bit set to a value indicative of configuring and activating only the target instance. As shown in FIG. 8, the boot sequence control bits provide boot_mode=0 and target=2′b0x to configure and activate instance 0. For some implementations, the instance controller 405 may make a 1−+0−+1 (e.g., a 1−+0 and then a 0−+1 transition) on a pin of the PLD 410. The 1−+0 transition starts a configuration port arbitration. The 0−+1 transition without SSPI configuration activation key enables MSPI. The MSPI of the PLD 410 may operate with the instance controller 405 (e.g., the boot controller of the instance controller 405) and reads an image (e.g., an FPGA image) including configuration data from a memory 805 (e.g., an external memory/flash device such as the memory 134). This image may be referred to as a current image and may be provided as a configuration bitstream to configure/program the PLD 410. In some cases, the instance controller 405 (e.g., the boot controller of the instance controller 405) may indicate to the configuration block of the PLD 410 an offset address in the memory 805 that stores the image for programming the PLD 410. As an example, the instance controller 405 (e.g., its boot controller) may indicate the offset address by sending a jump address (e.g., Addr #C in FIG. 8) to the configuration block of the PLD 410.

In operation 825, the PLD 410 is configured/programmed using the configuration data stored on the memory 805 (e.g., at the offset address provided to the PLD 410 by the instance controller 405). Configuration (e.g., MSPI configuration) of the PLD 410 may be performed using the configuration block of the PLD 410. In operation 830, the PLD 410 asserts a done signal (e.g., a done flag) indicating programming of the PLD 410 is successful/complete. The done signal may be transmitted by the PLD 410 to the instance controller 405 and/or the done signal may be stored in memory accessible to the instance controller 405 to identify configuration status associated with the PLD 410. After the PLD 410 is programmed, the PLD 410 starts to run in the background (e.g., with the done signal asserted). In operation 835, the instance controller 405 (e.g., its boot controller) activates the PLD 410 in response to getting the done signal. As part of activating the PLD 410, the instance controller 405 may set the active signal to 1 to indicate the PLD 410 is in the active state. After the PLD 410 is activated, the PLD 410 is in active operation to provide its PLD functionality.

In some aspects, the boot up sequence control bits may be updated to control the boot up sequence at a next power up. For example, the boot up sequence control bits may be updated if needed such that the current active instance (e.g., the instance that is active just prior to power down) is the instance the boot up sequence control bits indicates will become the active instance at the next boot up. In some cases, the boot up sequence control bits may be updated by user PFR associated with the active instance. In some cases, UFM of the instance controller 405 may be accessible through ICC-AHBL.

As provided above, in FIG. 8, the boot sequence control bits provide boot_mode=0 and target=2′box to configure and activate instance 0. As another example, the boot sequence control bits may provide target=2′blx and boot_mode=0 to configure and activate instance 1. As another example, the boot sequence control bits may provide target=2′b01 and boot_mode=1 to configure instance 1, and configure and activate instance 0. In this example, instance 1 may run in listen mode. As another example, the boot sequence control bits may provide target=2′b10 and boot_mode=1 to configure instance 0, and configure and activate instance 1. In this example, instanceOmay run in listen mode. As another example, the boot sequence control bits may provide target=2′bl1 or 2′b00 and boot_mode=1. In this example, after boot up, nothing is done by or on the PLDs 410 and 415.

In some embodiments, during boot up, a PLD (e.g., a logic instance) may fall back to a golden image in the event of a configuration failure of the PLD. During boot up, the instance controller 405 initiates MSPI configuration at boot up for each instance. Each instance may read contents (e.g., configuration data) based on a jump address from the instance controller 405. If everything is normal (e.g., configuration of each instance is successful), each instance asserts its respective done flag/signal. Ifan error occurs (e.g., including a bitstream authentication error) for a given instance, a done flag/signal is not asserted for the instance and a corresponding error code is set. The instance controller 405 may check the done signal and, if the done signal is not asserted (after a timeout period has elapsed), the instance controller 405 indicates a failure of the configuration.

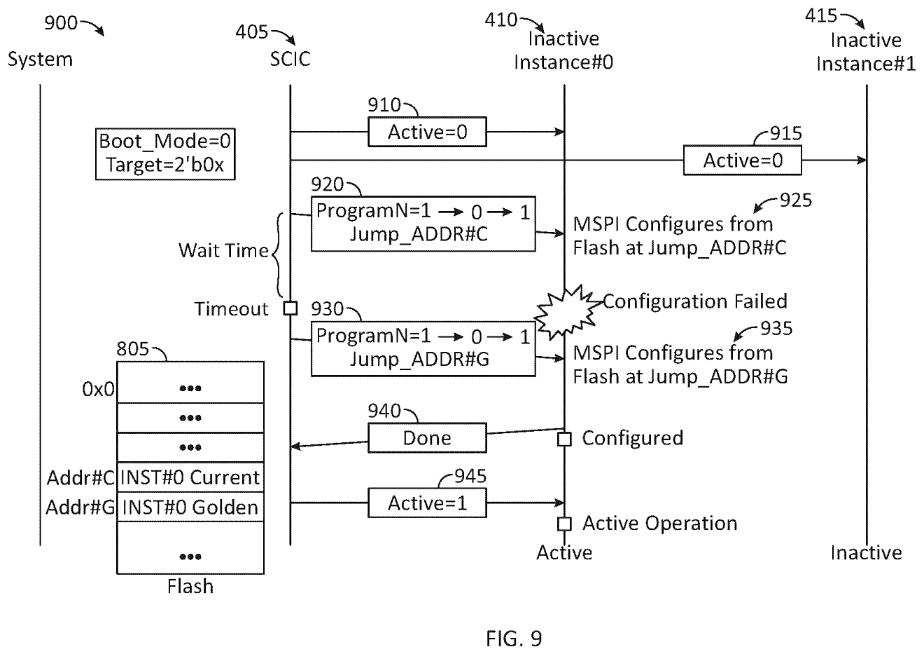

FIG. 9 illustrates a flow diagram of an example process 900 for falling back to a golden image during boot up in accordance with one or more embodiments of the present disclosure. In an aspect, a golden image may also be referred to, by way of non-limiting examples, as a fallback image, a base image, or a master image. Although, for explanatory purposes, the process 900 is described with reference to systems, devices, processes, and elements of FIG. 4, the process 900 may be performed by other systems, devices, and elements, and including a different selection of electronic systems, devices, elements, assemblies, and/or arrangements. At the initiation of the process, various system parameters may be populated by prior execution of a process similar to the process, for example, or may be initialized to zero and/or one or more values corresponding to typical, stored, and/or learned values derived from past operation of the process. Note that one or more operations may be combined, omitted, and/or performed in a different order as desired.

In operation 910, the instance controller 405 initially sets the PLD 410 to an inactive state, as shown by an active signal (e.g., an active flag) set to 0. In operation 915, the instance controller 405 initially sets the PLD 415 to an inactive state, as shown by an active signal set to 0.

In operation 920, the instance controller 405 (e.g., its boot controller) transmits one or more control signals to cause configuration of the PLD 410 using a current image stored on the memory 805 (e.g., an external flash device). In some aspects, the instance controller 405 uses an MSPI configuration of a configuration block of the PLD 410 (e.g., the target instance) per boot sequence control bits. For performing operation 920, the boot sequence control bits may have a target instance identifier set to 0 to identify the PLD 410 and a boot mode bit set to a value indicative of configuring and activating only the target instance. For some implementations, the instance controller 405 may make a 1-0-1 transition on a pin of the PLD 410. The 1-0 transition starts a configuration port arbitration. The O-1 transition without SSPI configuration activation key enables MSPI. The MSPI of the PLD 410 operates with the instance controller 405 (e.g., its boot controller) and reads the current image from the memory 505. This current image may be provided as a configuration bitstream to program the PLD 410. In some cases, the instance controller 405 (e.g., its boot controller) may indicate to the configuration block of the PLD 410 an offset address (e.g., a jump address Addr #C) in the memory 805 that stores the current image for programming the PLD 410. In operation 925, the PLD 410 is configured/programmed using the current image stored on the memory 805 (e.g., at the offset address provided to the PLD 410 by the instance controller 405). Configuration (e.g., MSPI configuration) of the PLD 410 may be performed using the configuration block of the PLD 410. It is noted that operations 910, 915, 920, and 925 generally correspond to operations 810, 815, 820, and 825, respectively, of the process 800.

The configuration of the PLD 410 fails. In operation 930, the instance controller 405 (e.g., its boot controller) transmits one or more control signals to cause configuration of the PLD 410 using a golden image stored on the memory 805. Similar to operation 920, the instance controller 405 may make a 1 −−−+0 −−−+1 transition on the pin of the PLD 410 to start the configuration port arbitration and enable MSPI. The instance controller 405 (e.g., its boot controller) may indicate to the configuration block of the PLD 410 an offset address (e.g., a jump address Addr #G) associated with a location in the memory 805 at which the golden image for programming the PLD 410 is stored. As shown in the process 900, the instance controller 405 may wait for a wait time (e.g., settable by a manufacturer and/or a user of the instance controller 405) for a done signal (e.g., a done flag) to be asserted by the PLD 410 to indicate configuration of the PLD 410 is successful and perform operation 930 at around an end of the wait time in response to not receiving the done signal. A start of the wait time may be around a time at which operation 920 has been or is being performed by the instance controller 405.

In operation 935, the PLD 410 is configured/programmed using the golden image (e.g., at the offset address provided to the PLD 410 by the instance controller 405). Configuration (e.g., MSPI configuration) of the PLD 410 may be performed using the configuration block of the PLD 410. In operation 940, the PLD 410 asserts a done signal (e.g., a done flag) indicating programming of the PLD 410 using the golden image is successful/complete. The done signal may be transmitted by the PLD 410 to the instance controller 405 and/or the done signal may be stored in memory accessible to the instance controller 405 to identify configuration status associated with the PLD 410. After the PLD 410 is programmed, the PLD 410 starts to run in the background. In operation 945, the instance controller 405 (e.g., its boot controller) activates the PLD 410 in response to getting the done signal. The instance controller 405 may activate the PLD 410 by setting the active signal to 1 to indicate the PLD 410 is in the active state. After the PLD 410 is activated, the PLD 410 is in active operation. After the process 900, the PLD 410 transitions from the inactive state to the active state and the PLD 415 remains in the inactive state. The PLD 410 is in active operation to provide its PLD functionality.

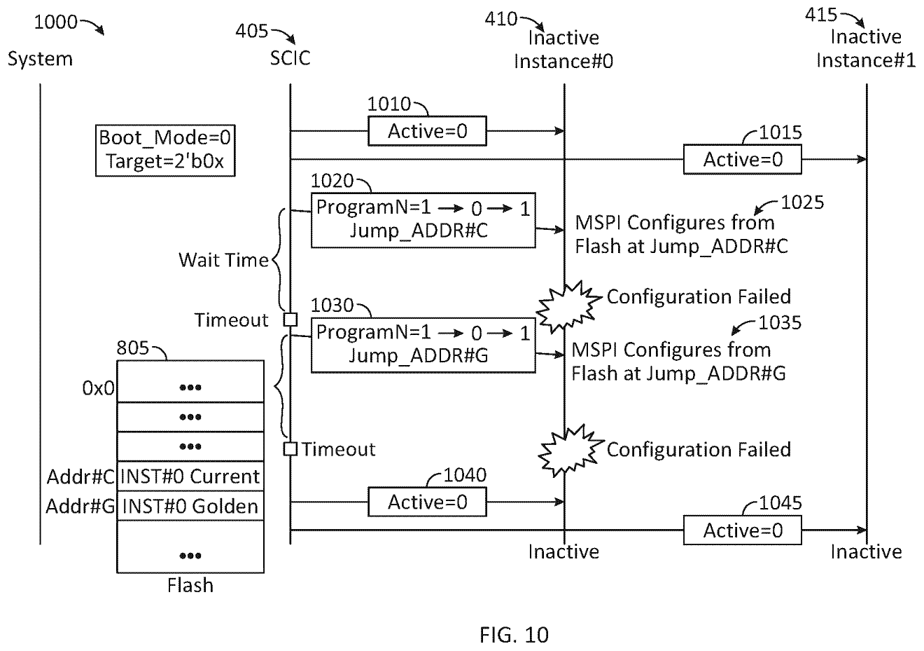

FIG. 10 illustrates a flow diagram of an example process 1000 for falling back to a golden image during boot up in accordance with one or more embodiments of the present disclosure. In an aspect, a golden image may also be referred to, by way of non-limiting examples, as a fallback image, a base image, or a master image. Although, for explanatory purposes, the process 1000 is described with reference to systems, devices, processes, and elements of FIG. 4, the process 1000 may be performed by other systems, devices, and elements, and including a different selection of electronic systems, devices, elements, assemblies, and/or arrangements. At the initiation of the process, various system parameters may be populated by prior execution of a process similar to the process, for example, or may be initialized to zero and/or one or more values corresponding to typical, stored, and/or learned values derived from past operation of the process. Note that one or more operations may be combined, omitted, and/or performed in a different order as desired.

Operations 1010, 1015, 1020, and 1025 may be the same or similar to operations 910, 915, 920, and 925, respectively of the process 900. In operation 1030, after a wait time from operation 920, the instance controller 405 (e.g., its boot controller) transmits one or more control signals to cause configuration of the PLD 410 using a golden image stored on the memory 805. In some cases, the instance controller 405 (e.g., its boot controller) may indicate to the configuration block of the PLD 410 an offset address (e.g., a jump address Addr #G) in the memory 805 that stores the golden image for programming the PLD 410. In operation 1035, the PLD 410 is configured/programmed using the golden image stored on the memory 505 (e.g., at the offset address provided to the PLD 410 by the instance controller 405). Configuration (e.g., MSPI configuration) of the PLD 410 may be performed using the configuration block of the PLD 410. It is noted that operations 1030 and 1035 generally correspond to operations 1020 and 1025, respectively.

The configuration of the PLD 410 using the golden image fails. In operation 1040, the instance controller 405 sets the PLD 410 to an inactive state. In operation 1045, the instance controller 405 sets the PLD 415 to an inactive state 0. As shown in the process 1000, the instance controller 405 may wait for the wait time for a done signal and perform operation 1040 at around an end of the wait time in response to not receiving the done signal. A start of the wait time may be around a time at which operation 1030 has been or is being performed by the instance controller 405. In some cases, after the process 1000, the instance controller 405 may attempt a number of times (e.g., set by a manufacturer and/or a user of the instance controller 405, the PLD 410, and/or the PLD 415) to configure using a predetermined set of one or more images (e.g., by performing the same or similar operations as operations 1020/1030 and 1025/1035). The image(s) used in the attempts may include the golden image, the image at jump address Addr #C, and/or other image(s), and may be specified by the manufacturer and/or the user.

After boot up, the instance controller 405 (e.g., its boot controller) uses an SSPI of a configuration block of a PLD (e.g., the PLD 410 and/or 415) to configure the PLD. FIG. 11 illustrates a flow diagram of an example process 1100 for configuration of the PLD 410 after boot up in accordance with one or more embodiments of the present disclosure. Although, for explanatory purposes, the process 1100 is described with reference to systems, devices, processes, and elements of FIG. 4, the process 1100 may be performed by other systems, devices, and elements, and including a different selection of electronic systems, devices, elements, assemblies, and/or arrangements. At the initiation of the process, various system parameters may be populated by prior execution of a process similar to the process, for example, or may be initialized to zero and/or one or more values corresponding to typical, stored, and/or learned values derived from past operation of the process. Note that one or more operations may be combined, omitted, and/or performed in a different order as desired.

In operation 1110, the instance controller 405 transmits an active signal to the PLD 410 indicating that the PLD 410 is an inactive instance (e.g., PLD 410's associated active signal has a value of 0). In operation 1115, the instance controller 405 transmits an active signal to the PLD 415 indicating that the PLD 415 is the active instance (e.g., PLD 415's associated active signal has a value of 1).

In operation 1120, an external system 1105 (e.g., a system controller/CPU external to the context switch device 400) sends a command to the instance controller 405 to cause configuration of the PLD 410. The external system 1105 may include any system used to control operation of the context switch device 400. In FIG. 11, the command is a context switching access control command (denoted as rcs_configure_sspi) with the instance number (e.g., #0 associated with the PLD 410). The command may be provided to a control SPI (CSPI) of the instance controller 405. In operation 1120, in response to the command from the external system 1105, the instance controller 405 sends a control signal to the PLD 410. The control signal may be or may include making a 1₋₋₊0 transition on a pin of the PLD 410 to start a configuration port arbitration process. In some cases, the instance controller 405 may include a context switch controller and boot controller. The context switch controller may intercept the command from the system 1105 and then instruct the boot controller to make the 1₋₋ 0 transition on the pin of the PLD 410. In some cases, the PLD 415 has been configured (e.g., using the MSPI) and activated during boot up, whereas the PLD 410 is configured (e.g., using the SSPI) after boot up by performing the process 1100. In operation 1125, the PLD 410 performs the configuration port arbitration process in response to the control signal from the instance controller 405.

In operation 1130, the system 1105 selects the PLD 410 (e.g., with an SCSNo signal whereOis the instance number of the PLD 410) asserted and sends an SSPI configuration activation key to the instance controller 405. In operation 1135, the PLD 410 activates its SSPI port such that the PLD 410 is ready to be configured upon receiving configuration data. In operation 1140, the system 1105 transmits configuration data (e.g., an appropriate FPGA bitstream) for configuring the PLD 410 over SSPI. As such, the configuration data may be referred to as SPI data (e.g., data provided over SPI). In operation 1145, the instance controller 405 bypasses (e.g., relays, directs, lets through) the SPI data to the PLD 410. The PLD 410 may decrypt the configuration data and program/configure its fabric (e.g., FPGA fabric). In operation 1150, the PLD 410 sets a done signal/flag in response to being configured successfully. After the successful configuration, the PLD 410 may start to run in the background with the done signal asserted.

In operation 1155, the system 1105 transmits a command (e.g., a get_status command) to the instance controller 405 and receives, in response to the command, the done signal indicating the PLD 410 has been configured successfully. In some cases, the get_status command may be used to obtain a status such as whether an instance is an active instance or an inactive instance, whether configuration of an instance is successful or not, whether context switching is successful or not, and/or others. After the process 1100, the PLD 415 remains the active instance and continues to provide its PLD functionality, whereas the PLD 410 remains inactive and has been configured. In some cases, the instance controller 405 may subsequently perform a context switch to activate the PLD 410 (e.g., make the PLD 410 the active instance) and deactivate the PLD 415.

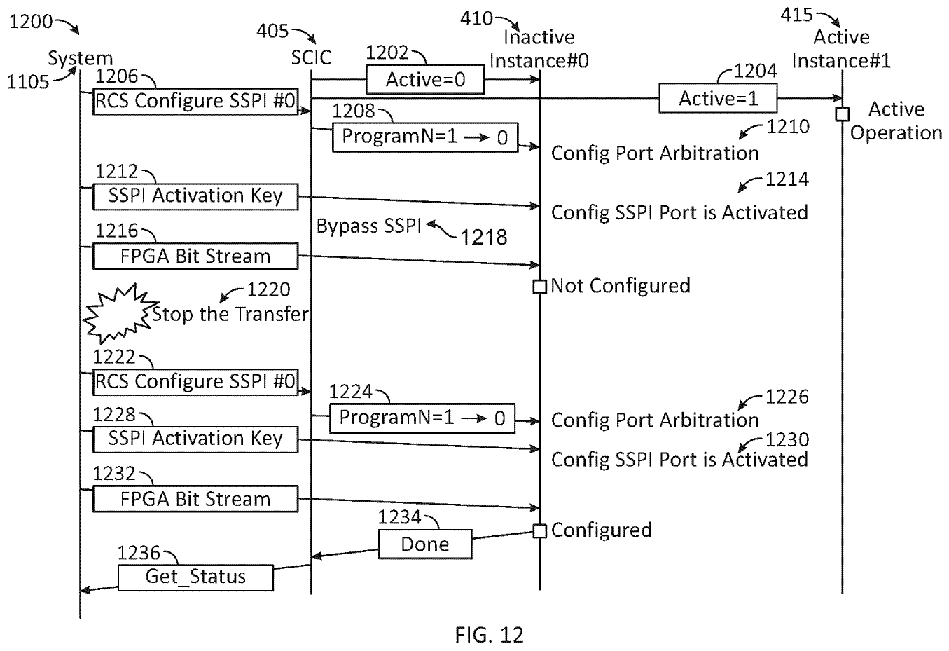

In some embodiments, in the SSPI mode, configuration may be restarted after halting (e.g., by the system 1105) of the configuration data (e.g., provided as a configuration bitstream) and/or configuration failure. FIG. 12 illustrates a flow diagram of an example process 1200 for halting and restarting configuration of the PLD 410 in accordance with one or more embodiments of the present disclosure. In FIG. 12, the PLD 415 is the active instance and the PLD 410 is an inactive instance. As the process 1200 is performed, the PLD 415 is in active operation. Although, for explanatory purposes, the process 1200 is described with reference to systems, devices, processes, and elements of FIG. 4, the process 1200 may be performed by other systems, devices, and elements, and including a different selection of electronic systems, devices, elements, assemblies, and/or arrangements. At the initiation of the process, various system parameters may be populated by prior execution of a process similar to the process, for example, or may be initialized to zero and/or one or more values corresponding to typical, stored, and/or learned values derived from past operation of the process. Note that one or more operations may be combined, omitted, and/or performed in a different order as desired.

In operation 1202, the instance controller 405 transmits an active signal to the PLD 410 indicating that the PLD 410 is an inactive instance (e.g., PLD 410's associated active signal has a value of 0). In operation 1204, the instance controller 405 transmits an active signal to the PLD 415 indicating that the PLD 415 is the active instance (e.g., PLD 415's associated active signal has a value of 1).

In operation 1206, the external system 1105 sends a command to the instance controller 405 to cause configuration of the PLD 410. The command may be provided to a CSPI of the instance controller 405. In operation 1208, in response to the command from the external system 1105, the instance controller 405 sends a control signal to the PLD 410. The control signal may be or may include making a 1 0 transition on a pin of the PLD 410. In some cases, the PLD 410 is configured using the SSPI. In operation 1210, the PLD 410 performs the configuration port arbitration process in response to the control signal from the instance controller 405.

In operation 1212, the external system 1105 selects the PLD 410 (e.g., with an SCSNo signal whereOis the instance number of the PLD 410) asserted and sends an SSPI configuration activation key to the instance controller 405. In operation 1214, the PLD 410 activates its SSPI port such that the PLD 410 is ready to be configured upon receiving configuration data. In operation 1216, the system 1105 transmits configuration data (e.g., an appropriate FPGA bitstream) for configuring the PLD 410 over SSPI. In operation 1218, the instance controller 405 bypasses (e.g., relays, lets through) the SPI data to the PLD 410. The PLD 410 may decrypt the configuration data and program/configure its fabric (e.g., FPGA fabric). In operation 1220, the instance controller 405 stops the transfer of the configuration data.

To restart the configuration of the PLD 410, operations 1222, 1224, 1226, 1228, 1230, and 1232 are performed. Operations 1222, 1224, 1226, 1228, 1230, and 1232 correspond to operations 1206, 1208, 1210, 1212, 1214, 1216, and 1218, respectively. In operation 1234, the PLD 410 sets a done signal in response to being configured successfully. In operation 1236, the system 1105 transmits a command (e.g., a get_status command) to the instance controller 405 and receives, in response to the command, the done signal indicating the PLD 410 has been configured successfully. After the process 1200, the PLD 415 remains the active instance and continues to perform its logic functions, whereas the PLD 410 remains inactive and has been configured. In some cases, the instance controller 405 may subsequently perform a context switch to activate the PLD 410 (e.g., make the PLD 410 the active instance) and deactivate the PLD 415.

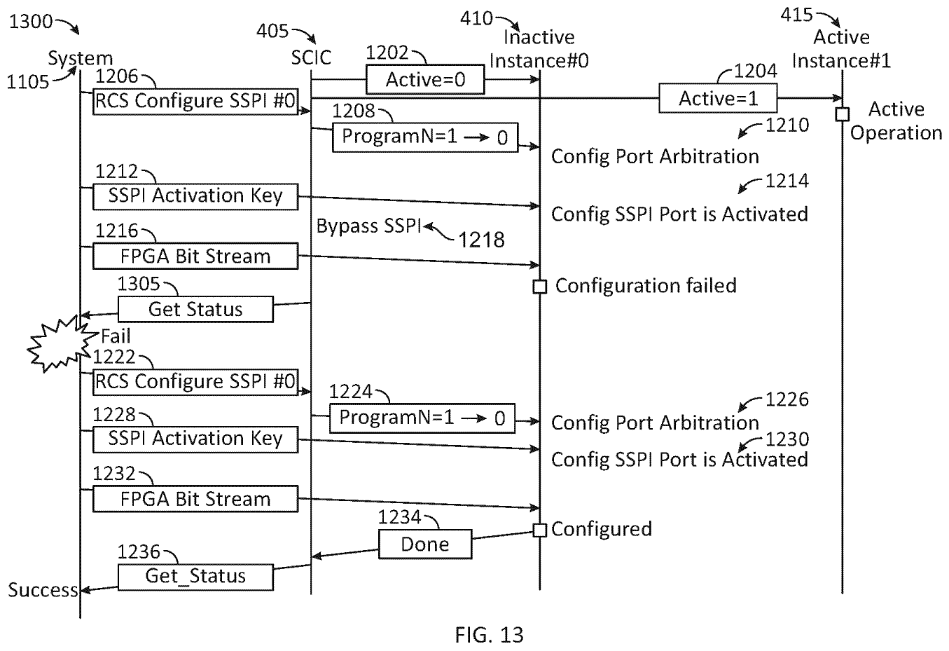

FIG. 13 illustrates a flow diagram of an example process 1300 for restarting configuration of the PLD 410 after configuration failure in accordance with one or more embodiments of the present disclosure. In FIG. 13, the PLD 415 is the active instance and the PLD 410 is an inactive instance. As the process 1300 is performed, the PLD 415 is in active operation. Although, for explanatory purposes, the process 1300 is described with reference to systems, devices, processes, and elements of FIG. 4, the process 1300 may be performed by other systems, devices, and elements, and including a different selection of electronic systems, devices, elements, assemblies, and/or arrangements. At the initiation of the process, various system parameters may be populated by prior execution of a process similar to the process, for example, or may be initialized to zero and/or one or more values corresponding to typical, stored, and/or learned values derived from past operation of the process. Note that one or more operations may be combined, omitted, and/or performed in a different order as desired.

The description of FIG. 12 generally applies to FIG. 13, with examples of differences between FIG. 12 and FIG. 13 and other description provided herein. As shown in FIG. 13, the process 1300 has operation 1305 whereas remaining operations can be implemented similar to or the same as corresponding operations in the process 1200 of FIG. 12. In operation 1305, the system 1105 transmits a command to the CSPI to receive a done signal and receives the done signal having a value indicating configuration of the PLD 410 failed.

Although the foregoing description in FIGS. 8-10 illustrates embodiments in which an interface associated with a first protocol (e.g., MSPI) is used for configuring an in instance during boot up and FIGS. 11-13 illustrate embodiments in which an interface associated with a second protocol (e.g., SSPI) different from the first protocol is used for configuring an instance after boot up, other embodiments may configure an instance during boot up and/or after boot up differently from that described with respect to FIGS. 8-13. As an example, interfaces associated with the same protocol may be used to configure an instance during boot up and after boot up. As another example, interfaces different from those identified above with respect to FIGS. 8-13 may be used for configuring an instance.

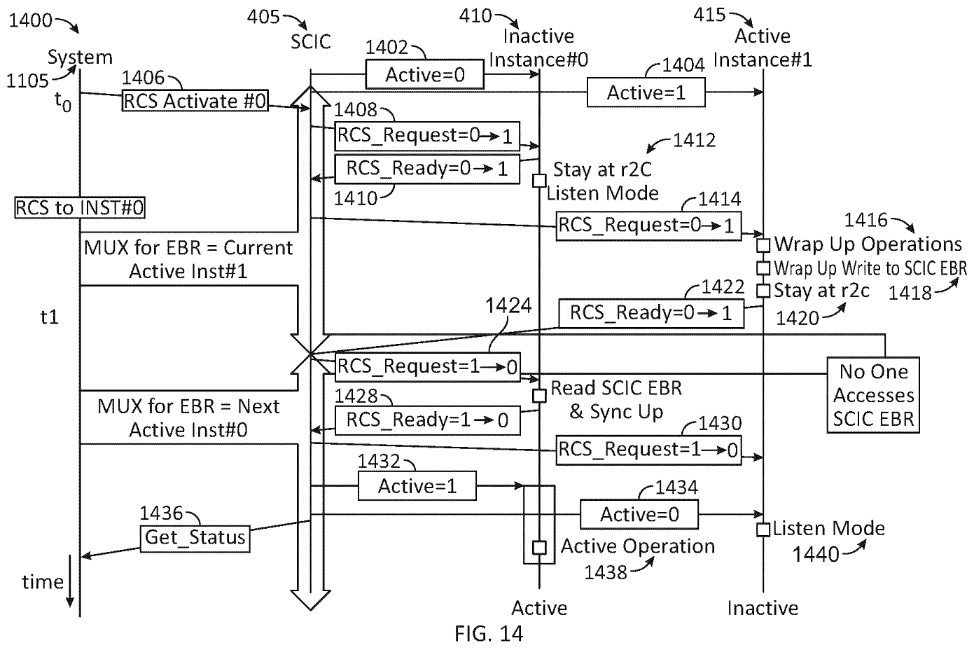

FIG. 14 illustrates a flow diagram of an example process 1400 for context switching from the PLD 410 to the PLD 415 in accordance with one or more embodiments of the present disclosure. In this regard, at a start of the process 1400, the PLD 415 is the active instance and the PLD 410 is an inactive instance. Although, for explanatory purposes, the process 1400 is described with reference to systems, devices, processes, and elements of FIG. 4, the process 1400 may be performed by other systems, devices, and elements, and including a different selection of electronic systems, devices, elements, assemblies, and/or arrangements. At the initiation of the process, various system parameters may be populated by prior execution of a process similar to the process, for example, or may be initialized to zero and/or one or more values corresponding to typical, stored, and/or learned values derived from past operation of the process. Note that one or more operations may be combined, omitted, and/or performed in a different order as desired.

In operation 1402, the instance controller 405 transmits an active signal to the PLD 410 indicating that the PLD 410 is an inactive instance (e.g., PLD 410's associated active signal has a value of 0). In operation 1404, the instance controller 405 transmits an active signal to the PLD 415 indicating that the PLD 415 is the active instance (e.g., PLD 415's associated active signal has a value of 1).

In operation 1406, the system 1105 transmits a command to the instance controller 405 to initiate a context switching (e.g., RCS in some cases) flow/process that activates the PLD 410 (e.g., to set the PLD 410 as the active instance). The command to activate the PLD 410 may be sent to the CSPI and then the context switch controller may start the context switching flow. In some cases, such a context switch may be started only if a done signal is asserted on the targeted instance (e.g., the done signal indicates the targeted instance is successfully configured).

In operation 1408, the instance controller 405 transmits a request to the PLD 410 to request context switching to switch/transition the PLD 410 from being an inactive instance to the active instance. As shown in FIG. 14, the request may be or may include a 0 1 transition made to a signal denoted as rcs_request by the instance controller 405 (e.g., its RCS controller).

In operation 1410, the PLD 410 goes into R2C state and transmits an indication to the instance controller 405 that the PLD 410 is in the R2C state. As shown in FIG. 14, the indication from the PLD 410 may be or may include a O-1 transition made to a signal denoted as rcs_ready by the PLD 410. In operation 1412, the PLD 410 enters a listen mode (e.g., for further commands and/or requests from the instance controller 405) and stays in the R2C state.

In operation 1414, the instance controller 405 transmits a request to the PLD 415 to request context switching to switch/transition the PLD 415 from being the active instance to an inactive instance. The request to the PLD 415 may be transmitted responsive to the O-1 transition made to the rcs_ready signal by the PLD 410. As shown in FIG. 14, the request from the instance controller 405 may be or may include a O-1 transition made to the signal rcs_request by the instance controller 405 (e.g., its RCS controller). This may become an interrupt to a CPU of the PLD 415. In operation 1416, the PLD 415 (e.g., the current active instance) completes (e.g., wraps up) any on-going operations in a normal/appropriate way. In operation 1418, the PLD 415 writes any information for the PLD 410 (e.g., message over the context switch) in the memory 425 (e.g., EBR) of or coupled to the instance controller 405. In operation 1420, the PLD 415 stays in an R2C state. In operation 1422, the PLD 415 transmits an indication to the instance controller 405 that the PLD 415 is in the R2C state. As shown in FIG. 14, the indication from the PLD 415 may be or may include a O-1 transition made to the signal rcs_ready by the PLD 415. This may use the GPIO of the CPU of the PLD 415.

In operation 1424, the instance controller 405 (e.g., its RCS controller) transmits a request to the PLD 410 to request context switching to switch/transition the PLD 410 from being an inactive instance to the active instance. As shown in FIG. 14, the request may be or may include a 1-0 transition made to the signal res_request by the instance controller 405 (e.g., its RCS controller). This is a 1-0 transition that follows the O-1 transition performed in operation 1408. In operation 1426, the PLD 410 reads the memory 425 of or coupled to the instance controller 405 to synchronize based on data written to the memory 425 by the PLD 415 in operation 1418. Such data may include synchronization data/values to synchronize the PLD 410 to a correct initial state. In operation 1428, the PLD 410 transmits an indication to the instance controller 405 that the data from the memory 425 has been read (e.g., and the context switching flow may continue). As shown in FIG. 14, the indication may be or may include a 1 −−−−−+0 transition made to the signal rcs_ready by the PLD 415. This is a 1 −−−−+0 transition that follows the 0 −−−−−+1transition performed in operation 1410. In operation 1430, the instance controller 405 transmits a request to the PLD 415 to request context switching to switch/transition the PLD 415 from the active instance to an inactive instance. As shown in FIG. 14, the request may be or may include a 1−−+0 transition made to the signal res_request by the instance controller 405. This is a 1 −−−−−+0 transition that follows the 0−−−−−+1transition performed in operation 1414.

In operation 1432, the instance controller 405 sets the active signal associated with the PLD 410 to the active, state. In operation 1434, the instance controller 405 sets the active signal associated with the PLD 415 to the inactive state. In some cases, there may be intentional overlap in the active signals of the PLDs 410 and 415. In operation 1436, the system 1105 transmits a command (e.g., a get_status command) to the instance controller 405 (e.g., to the CSPI) to receive context switching operation result (e.g., to confirm an active state and an inactive state of each instance after the context switching operation is correct). After the process 1400, the PLD 410 is the active instance and performs its PLD functionality (e.g., logic functions) and the PLD 415 is an inactive instance.

In some embodiments, during the context switching operation, data between the two instances can be transferred using the memory 425 (e.g., the EBR) associated with the instance controller 405 (e.g., as shown in operations 1418 and 1426) and/or dedicated ICC channels. In some cases, the data may be transferred using the memory 425. The memory 425 may be accessible from the active instance through an AHB-L bus connection until the active instance sends out the res_ready=0−−−−−+1transition to the instance controller 405 in response to the rcs_request=0 −−−−−+1transition from the instance controller 405. From that time on, the memory 425 is then accessible by the next active instance. The active instance can put a message/data into the memory 425 so later on the newly activated instance can retrieve the message/data from the memory 425 just before this newly activated instance becomes active. The newly activated instance reads the contents of the memory 425 before the newly activated instance can become active to synchronize the newly activated instance to the previous active instance (e.g., by commence starting the newly activated instance with the correct values passed by the previous active instance). Such synchronization facilitates a seemless transition from one instance as the active instance to another instance as the active instance and allows for uninterrupted coverage of desired functionality. In some cases, alternatively or in addition, dedicated ICC connections between the two instances may be used during the context switching operation. The user may use the dedicated ICC connections for ICC protocol (e.g., provided RTL module) and/or any other protocol such as UART, I2C, and so forth. The active instance may send a message/data to the background listening inactive instance. In some cases, this may need to be done only after the inactive instance is configured.

As shown in FIG. 14, during at least a time duration from to to t1, a multiplexer of or coupled to the instance controller 405 may allow the memory 425 to be accessed by the PLD 415 (e.g., the current active instance). The PLD 415 accesses the memory 425 to write data (e.g., synchronization data) to the memory 425. At around time t1, no instance accesses the memory 425. After time ti, the multiplexer may allow the memory 425 to be accessed by the PLD 410 (e.g., the next active instance). The PLD 410 accesses the memory 425 to read the data previously written to the memory 425 by the PLD 415 when the PLD 415 was the active instance.

Although in FIG. 14 the PLD 415 is the active instance, in some cases the PLD 415 is also an inactive instance (e.g., it was not configured during a boot mode such as in a do nothing boot mode). The instance controller 405 (e.g., its RCS controller) may know that the PLD 415 is inactive since the active signal of the PLD 415 is 0. The instance controller 405 may make a 1−−−−+O transition to the rcs_request of the PLD 410. The PLD 410 may read the memory 425 (e.g., EBR) to get possible initial message (e.g., synchronization values) and synchronize to a correct initial state. The PLD 410 may make a 1−−+0 transition to the rcs_ready of the PLD 410.

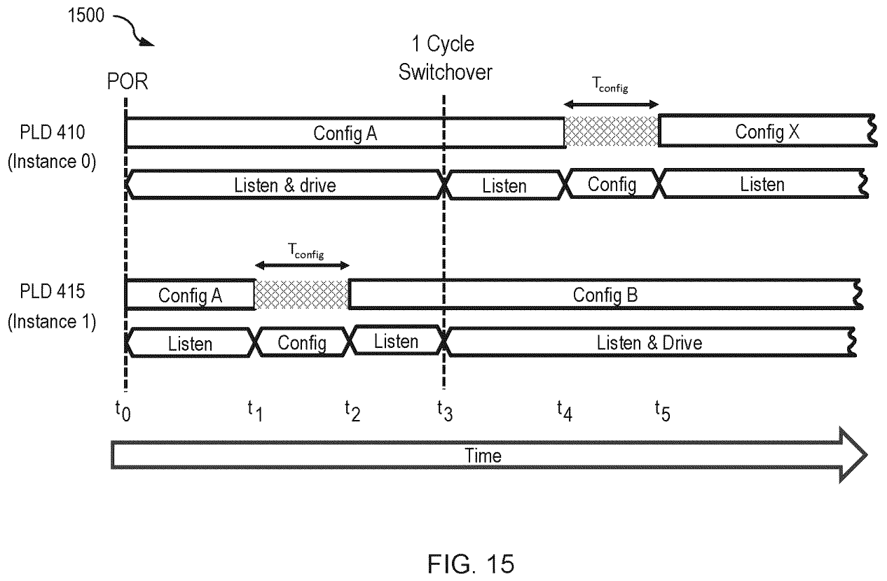

FIG. 15 illustrates a timing diagram 1500 associated with context switching from the PLD 410 (e.g., instance 0) to the PLD 415 (e.g., instance 1) in accordance with one or more embodiments in the present disclosure. For explanatory purposes, the timing diagram 1500 is described primarily with respect to the process 1400 of FIG. 14, although the timing diagram 1500 may be associated with other processes for context switching. It is noted that time durations between operations of the PLDs 410 and 415 shown in FIG. 15 are not necessarily to scale.

At around to, a power-on-reset (POR) event (e.g., also referred to as a power up event or a power-on event) of the PLDs 410 and 415 is complete. From to to t1, the PLD 415 has configuration data Config A loaded and is in the listen mode in which the PLD 415 is listening to various I/Os. The PLD 415 receives a request from the instance controller 405 to configure using configuration data Config Band activate once the PLD 415 is configured using Config B. From t1 to t2, the PLD 415 loads Config B to configure the PLD 415 according to Config B. Configuration of the PLD 415 may be within a time duration Tconfig. In some cases, the time duration Tconfig may be around 30 ms. From h to t3, the PLD 415 returns to the listen mode and performs operations (e.g., including synchronization operations) to transition the PLD 415 from the inactive state to the active state. In some cases, such operations may include those similar to or the same as operations 1426 and 1428 of the process 1400.

With reference to the PLD 410, from to to t3, the PLD 410 has Config A loaded and is the active instance. In this regard, the PLD 410 is in the listen and drive mode in which the PLD 410 is listening to various I/Os as well as having write access to the shared I/Os of the I/O bank 430 directly controlled by the active instance. During to totJ, the PLD 410 receives a context switch request from the instance controller 405 to request the PLD 410 to transition from the active state to the inactive state. In response to the context switch request, the PLD 410 may wrap up operations, wrap up write to the memory 425 (e.g., EBR), maintain itself in a R2C state, and transmit a ready to change signal to the instance controller 405. In some cases, such operations may include those similar to or the same as operations 1416, 1418, 1420, and 1422 of the process 1400.

At around time t3, the active instance switches from being the PLD 410 to being the PLD 415. In some aspects, as shown in FIG. 15, the switchover from the PLD 410 being the active instance to the PLD 415 being the active instance is a one-cycle switchover. In this regard, PLD functionality may be provided by the PLD 410 at a first clock cycle and then PLD functionality is provided by the PLD 415 at a second clock cycle adjacent to the first clock cycle. A one-cycle switchover may generally be considered near instantaneous. Synchronization and switchover facilitate seemless transition from one instance as the active instance to another instance as the active instance and allow for uninterrupted coverage of desired functionality.

From t3 to 14, the PLD 410 has configuration data Config A loaded and is in the listen mode in which the PLD 410 is listening to various I/Os and receives a request from the instance controller 405 to configure using configuration data Config X. In some cases, the request may optionally include a request to activate the PLD 410 once the PLD 410 is configured using Config X. Config X may be Config B or other configuration data. From 14 to ts, the PLD 410 loads Config X to configure the PLD 410 according to Config X. Configuration of the PLD 415 may be within a time duration Tconfig. In some cases, the time duration Tconfig may be around 30 ms. After ts, the PLD 410 returns to the listen mode. With reference to the PLD 415, from t3 onwards, the PLD 415 has Config B loaded and is the active instance. In this regard, the PLD 415 is in the listen and drive mode in which the PLD 415 is listening to various I/Os as well as having write access to the shared I/Os of the 1/0bank 430 directly controlled by the active instance. In an embodiment, the PLD 410 and the PLD 415 may be operated in lockstep. In such an embodiment, Config X may be Config B such that a context switch from the PLD 410 and the PLD 415 would take over operations seemlessly. In some cases, Config B may be an updated version of Config A (e.g., the user makes updates to the user logic implemented using Config A).

Additional examples and information in accordance with one or more embodiments of the present disclosure are provided herein. A list of acronyms used throughout the present disclosure are provided in Table 1 below.

TABLE 1
Acronyms used in the present disclosure

| Acronym | Definition |
|---|---|
| AHB-L | Advanced High-performance Bus (Lite) |
| BW | Bandwidth |
| CFG | Configuration Block |
| CRAM | Configuration RAM |
| CSPI | Control Serial Peripheral Interface |
| EBR | Embedded Block RAM |
| EFB | Embedded Function Block |
| FSM | Finite State Machine |
| FW | Firmware |
| GPIO | General Purpose I/O |
| HP | High Performance |
| I/O | Input/Output |
| ICC | Inter-chip Communication |
| INST | Instance |
| INTR | Interrupt |
| JTAG | Joint Test Action Group |
| LC | Logic Cell |
| Mb | Mega Bits |
| MB | Mega Bytes |
| MCK | Manager Serial Peripheral Interface Clock |
| MISO | Manager In Subordinate Out |
| MOSI | Manager Out Subordinate In |
| MSPI | Manager Serial Peripheral Interface |
| MUX | Multiplexer |
| PCB | Printed Circuit Board |
| PIO | Physical I/O |
| PLL | Phase Locked Loop |
| R2C | Ready to Change State |
| RAM | Random Access Memory |
| RCS | Rapid Context Switch |
| RTL | Register-Transfer Level |
| sere | Secure Configuration Instance Control |
| SPI | Serial Peripheral Interface |
| SRAM | Static RAM |
| SSPI | Subordinate Serial Peripheral Interface |
| SW | Software |
| TDI | Test Data In |
| TDO | Test Data Out |
| TMS | Test Mode Select |
| UFM | User Flash Memory |
| WR | Wide Range |

### RCS Device Architecture Example

Manager device—device that initiates a transaction
Subordinate device—device responds to the transaction initiated by manager device

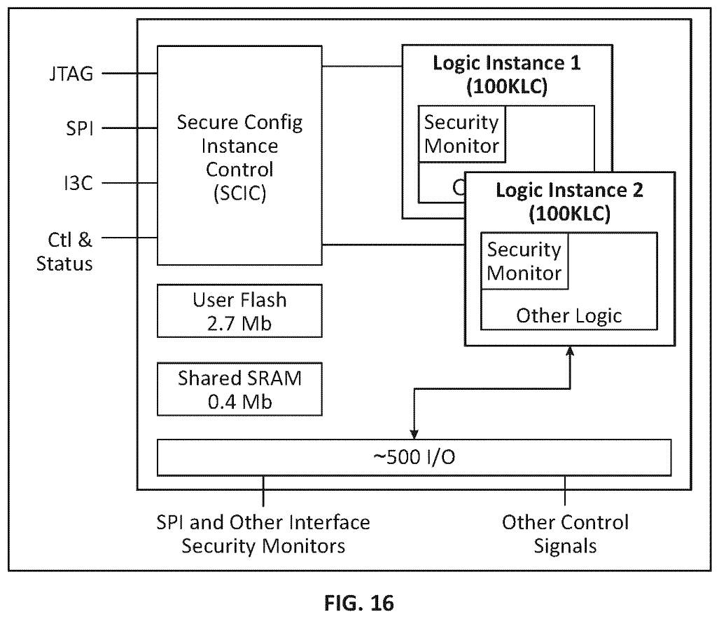

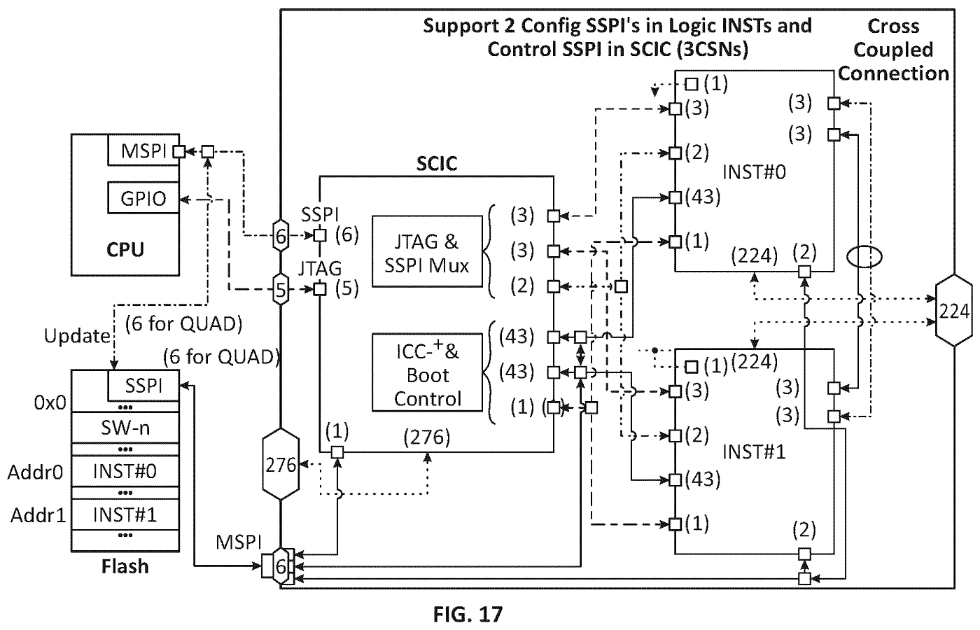

FIG. 16 illustrates an example context switch device/architecture in accordance with one or more embodiments of the present disclosure. FIG. 17 illustrates an RCS connection overview in accordance with one or more embodiments of the present disclosure. FIG. 17 details example context switching connections between instances and an instance controller (e.g., SCIC) in accordance with one or more embodiments.

### RCS Operation

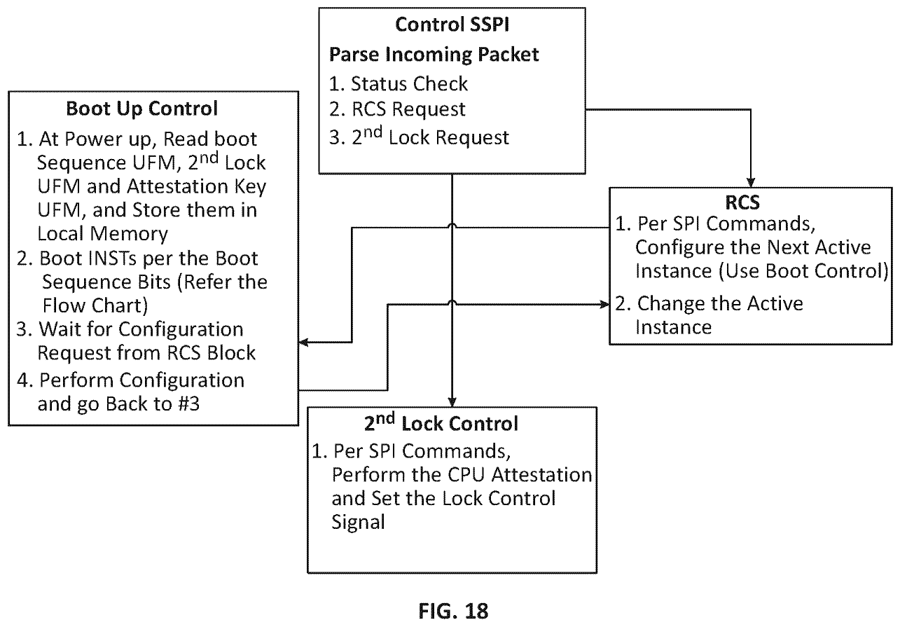

FIG. 18 illustrates a flow diagram of an example operation flow for a context switchdevice with [symbol] lock control in accordance with one or more embodiments of the present disclosure.

### Logic Instances and SCIC

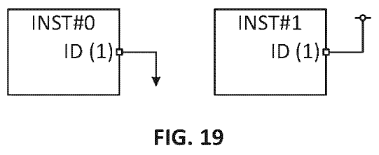

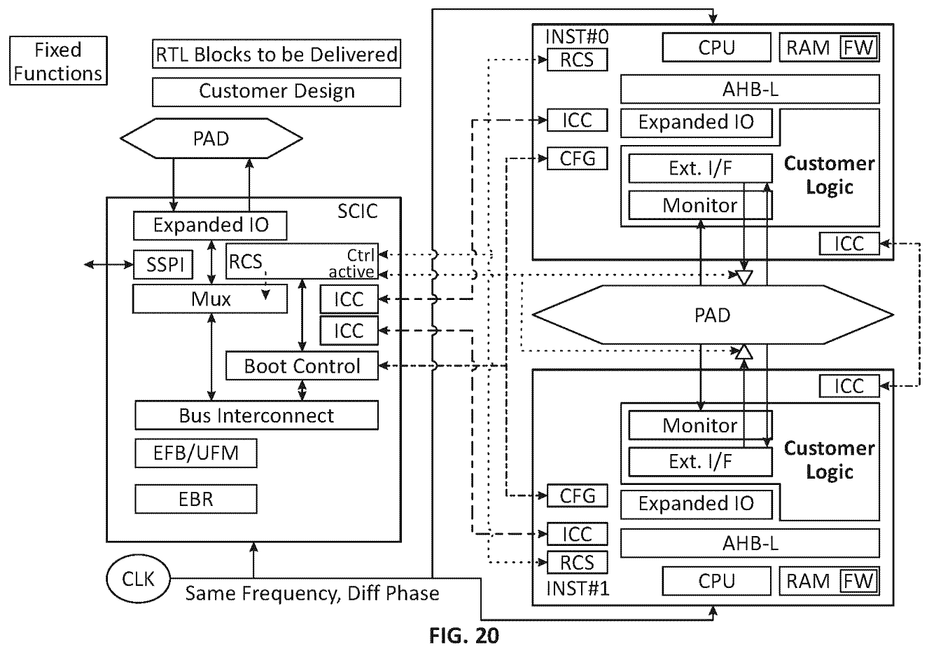

FIG. 19 illustrates examples of instance identification (ID) pins in accordance with one or more embodiments of the present disclosure. In FIG. 19, instance O (INST #0) has its instance identification pin driven low (e.g., logic 0) and instance 1 (INST #1) has its pin driven high (e.g., logic 1). FIG. 20 illustrates an RCS function overview including various context switching functions in accordance with one or more embodiments of the present disclosure.

### JTAG and SSPI Multiplexer

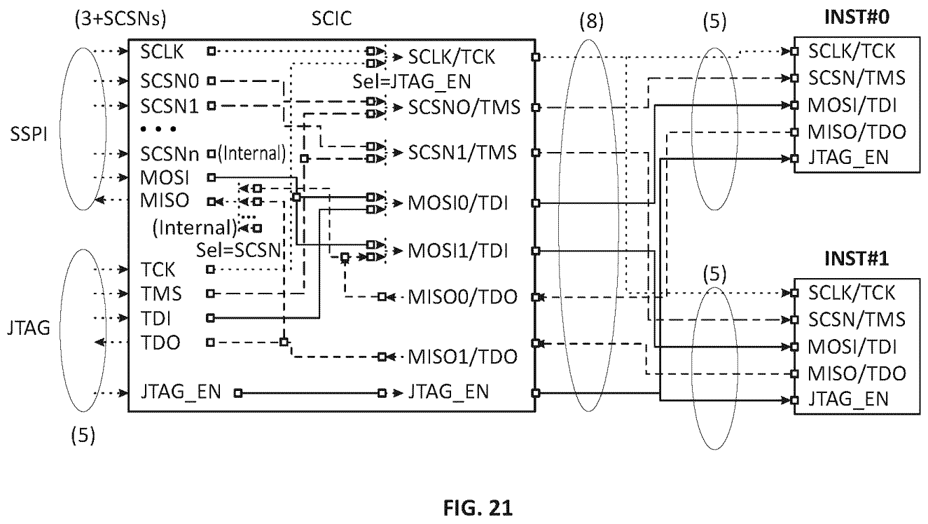

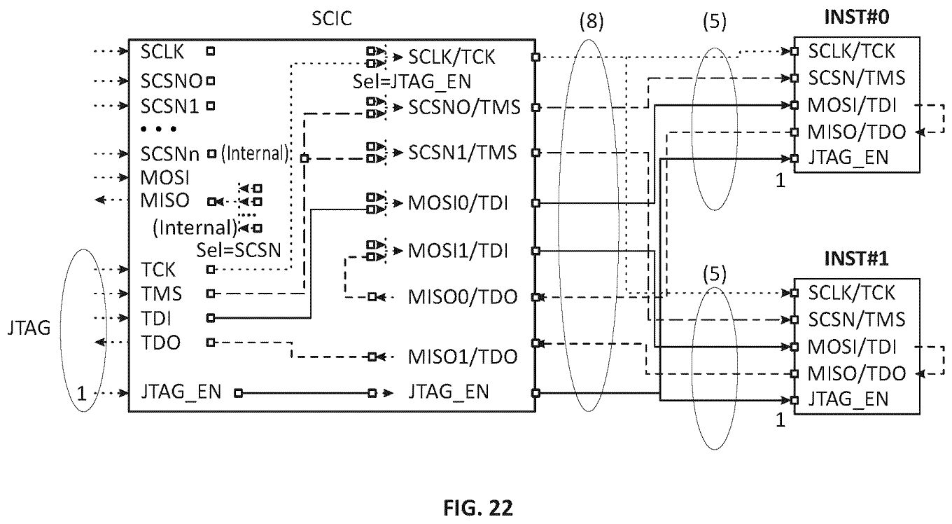

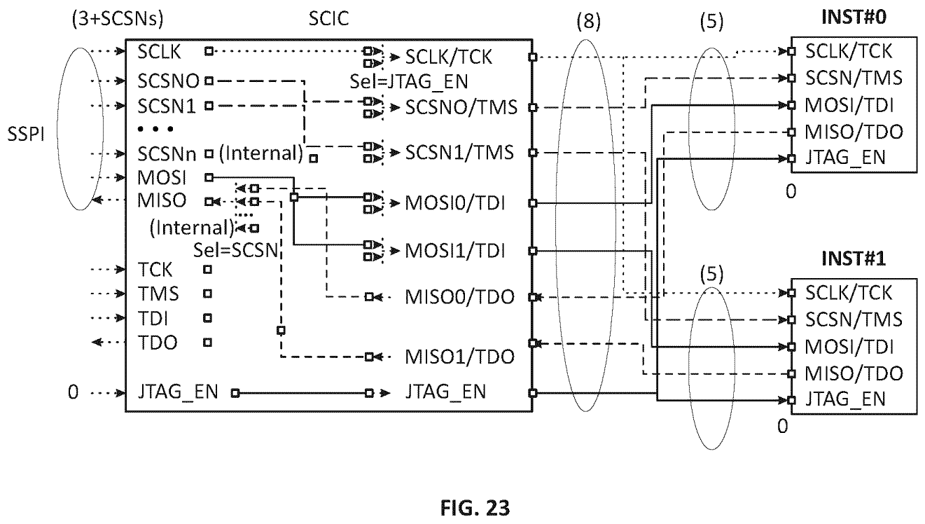

FIG. 21 illustrates an example of a JTAG & SSPI mux function and interface in accordance with one or more embodiments of the present disclosure. FIG. 22 shows the JTAG & SSPI mux function of FIG. 21 with JTAG mode enabled (JTAG_EN=1) in accordance with one or more embodiments of the present disclosure. Note that the TDI and TDO chain includes both instances and TCK and TMS are supplied to both instances. FIG. 23 shows the JTAG & SSPI mux function of FIG. 22 with SSPI mode enabled (JTAG_EN=0) in accordance with one or more embodiments of the present disclosure. SCLK and MOSI are supplied to both instances and MISO from each instance (and those from other SSPis in SCIC) are muxed per SCSN values to make a final MISO. Note that typically multiple MISOs are wired ORed. In the case of the SCIC, a mux is used.

### Inter-Chip Communications (ICC)

This function connects the instances to the resources in the SCIC so that user logic in the instances can use resources such as I/O, EBR, UFM in the SCIC seamlessly. There are two different ICCs that involve the SCIC:
ICC-AHB-L—connects the AHB-L bus in the instances to the SCIC so that a “CPU-like manager” device in the instances can access resources in the SCIC.
ICC-EIO—connects the expanded (or virtual) port of the instance user module to the I/O of the SCIC to support the expanded I/O feature

This function is composed of ICC TX and ICC RX modules (there are different modules for ICC-AHB-L and ICC-EIO). ICC also provides for passing context information between two instances (i.e., pass information from the current active instance to the next active instance). For example, this can be used to inform what events that were already handled (or not handled) by the active instance so that the next instance performs the correct actions upon becoming active.

ICC using AHB-L from INST to SCIC (ICC-AHB-L):
Use the AHBL2ICC manager and ICC2AHBL subordinate
   For one ICC, wires are used (some from manager to subordinate and others from subordinate to manager).
One ICC-AHBL between SCIC and INST #0 and one more ICC-AHBL between SCIC and INST #1

The data EIO block for bi-directional communication signals are:
clko, iw_start, iw_eio, clki, ir_start, ir_eio

The user may use other serial communication over the above connections:
UART/I2C requires some wires to have both of manager and subordinate modules

### Possible Protocols:

Current active instance: rcs_request move to r2c state send information to next active device rsc_ready
Next active instance: configuration listen mode receive information from current active instance active

There is also ICC for the direct (cross coupled) communications between two instances:
Cross-coupled 3-wire connection (bitstream is assumed to be instance neutral-RX connected to TX and vice versa).
For example, manager UART will be assigned to the same pins in both INSTs
In some cases, the user can choose one of these protocols: EIO, I2C, or UART

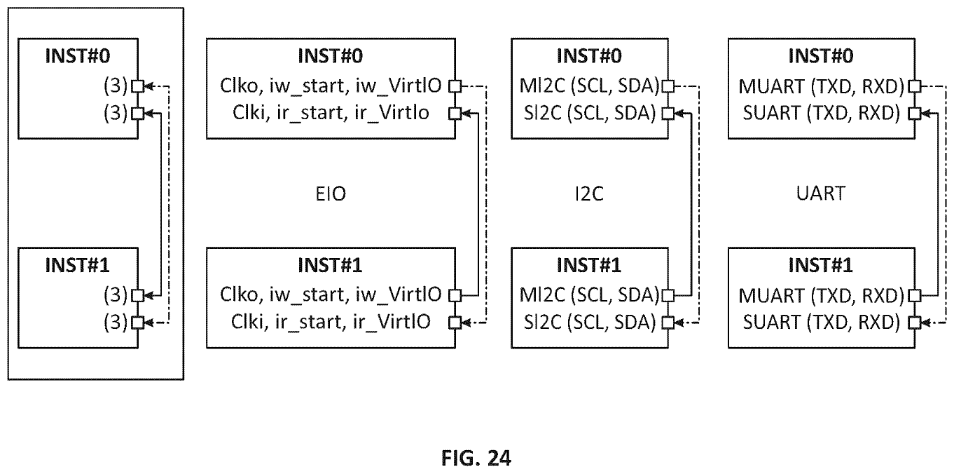

FIG. 24 summarizes various cross couple communication schemes (e.g., ICC over cross coupled connections) in accordance with one or more embodiments of the present disclosure.

### Expanded I/O (EIO)

Virtual1/0is shared between logic instances and SCIC (ICC-EIO):
ICC-EIOs between SCIC and instance #0 and ICC-EIOs between SCIC and instance #1
Each ICC-EIO uses wires (some wires from logic instance to SCIC and other wires from SCIC to logic instance)
   clkx and clkj oflCC-AHB-L are reused for ICC-EIO
Use of two ICC-EIOs for each logic instance:
   ICC-EIO0 and ICC-EIOl between each oflogic instance and SCIC
   Parameter “n” divides the EIOs between the two ICC-EIOs
      The first n EIOs are assigned to ICC-EIO0 and next 276-n go to ICC-EIO1
   This scheme can cover two different BW partitions
EIO to PIO (Physical IO) mapping in SCIC
   Pre-defined mapping
   For example, EIO1,2, and 3 are for ICC-EIO0 and they are mapped to physical IO #10, #12, and #14.

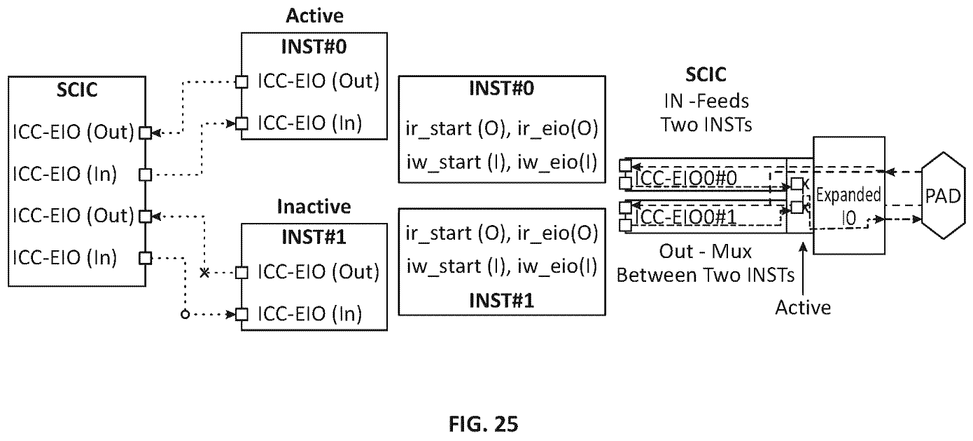

FIG. 25 illustrates an example virtual I/O (I/O expander) as set forth in accordance with one or more embodiments of the present disclosure.

### Configuration Overview

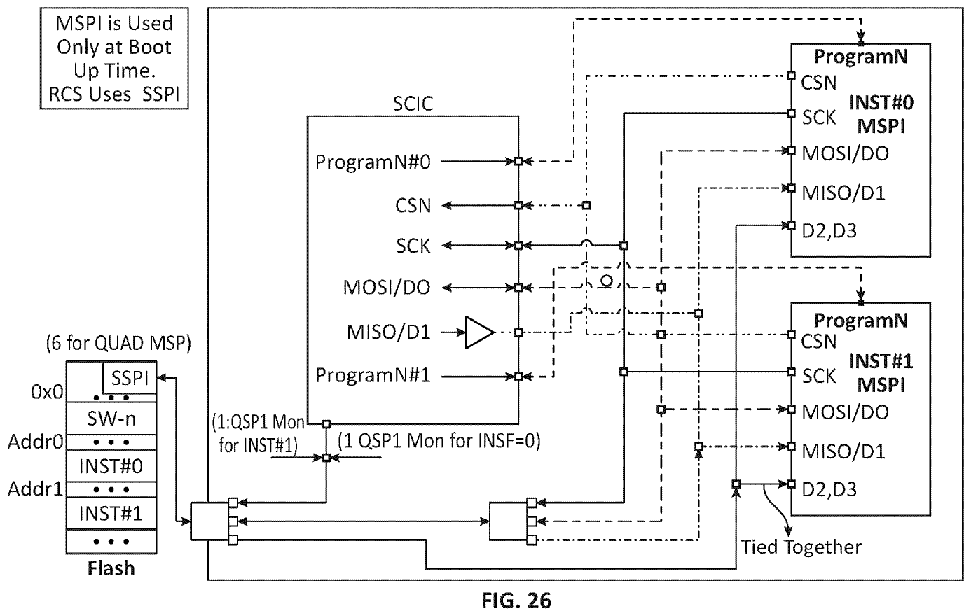

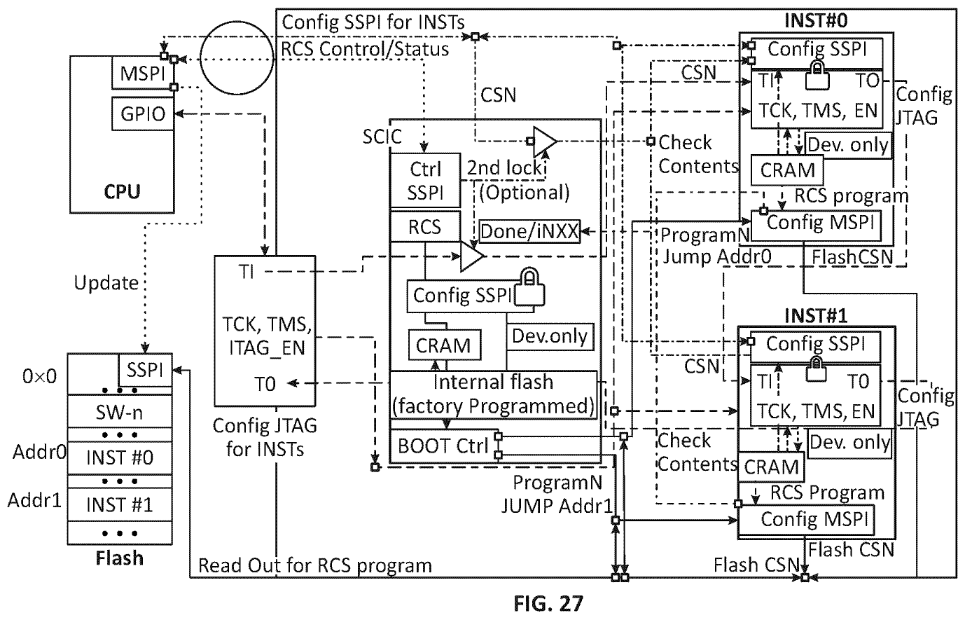

FIG. 26 illustrates example MSPI boot-up connections in accordance with one or more embodiments of the present disclosure. In this regard, FIG. 26 illustrates configuration and boot control associated with MSPI. FIG. 27 summarizes an example context switching configuration and boot control flow in accordance with one or more embodiments of the present disclosure.

### RCS User1/0Switchover Handling

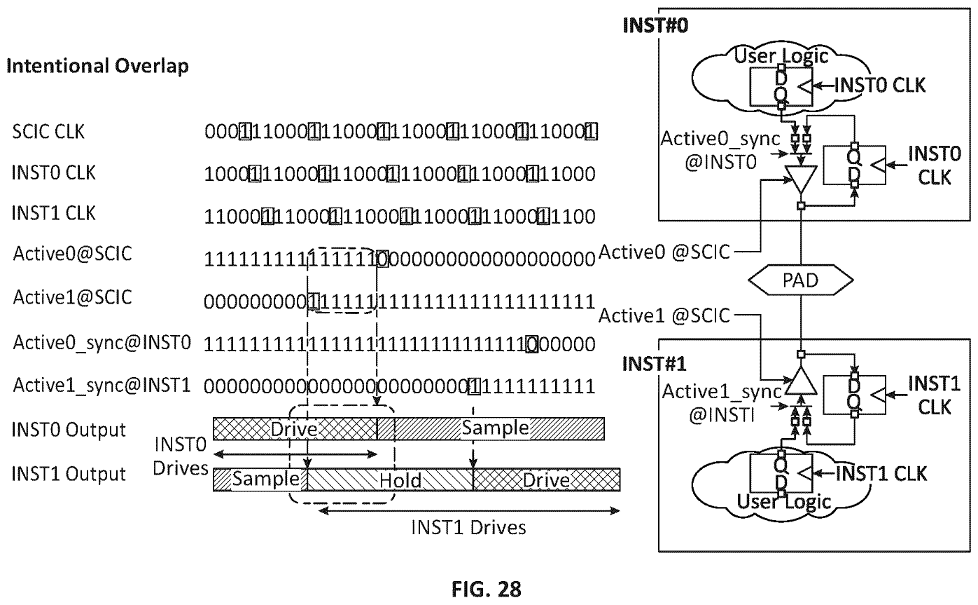

If the 1/0 output values during the R2C state of both instances are static but different, then the hold enabled I/O is used to prevent any short pulse during switchover from one instance to the other. FIG. 28 illustrates an example of such an operation in accordance with one or more embodiments of the present disclosure. As shown in FIG. 28, the SCIC intentionally overlaps the active #0 and active #1 for one cycle and at INST does the triple sync of active #{0,1}. This 1 cycle overlap removes any “no one drives” period (the sample and hold circuit makes the two instances drive the same value in the overlap time). The delay between the triple synced active at each instance and active at SCIC guarantees the >1 cycle hold time and prevents any short pulse (i.e., signal stretching).

### Protection of UFM From Live Update Failure

In accordance with one or more embodiments as set forth in the present disclosure, multiple copies of information may be used with corresponding valid bits to avoid failure of a live update. Instead of one information (multiple bits), 2 sets of {valid(1b), information}+1set of {information} are stored in UFM. When valid=1 it means that the information field is correctly updated.

Instead of a simple write to those bits in UFM with new_information, a series of 6 writes is performed:
copy #O-valid=0 copy #0-info=new_info copy #0-valid=1 copy #1-valid=0 copy #1-info=new_info copy #1-valid=1
Copy #2 is not updated. It is programmed with a default value in the factory Instead of a simple read of those bits in UFM, the below decision process is performed
If copy #0's valid==1, return copy #0's info else
if copy #1's valid==1, return copy #1's info else return copy #2's info

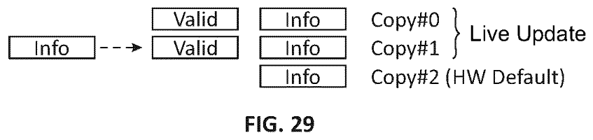

FIG. 29 illustrates the above-described example UFM protection scheme in accordance with one or more embodiments of the present disclosure. The above sequence of writes to those bits may be done by the user logic of the active instance. The user logic may use UFM for both of data that may need such a protection as well as data that may not need such a protection. In some cases, only user logic knows which data needs such a protection and which data do not. As such, the user logic in the active instance performs the above sequence of write for the protected data including lock bits and boot up sequence control bits.

The above decision process for read may be done by the SCIC's boot control logic at boot time when it copies the contents to the RAM. The output from the decision process (instead of the raw data) may be written to RAM for other blocks to use without being concerned about a live update failure.

The updated boot up sequence control bits in UFM have effect at the next boot up of the whole chip. For a lock bit, the write may also update the RAM bit so that it has the immediate effect after it is updated by the logic instance. If the user logic uses additional bits in UFM for the protected data, the user logic performs such a decision process over the read-out data in the user logic.

### UFM Contents

UFM contents are read out by boot control logic at boot up and stored in internal memory. The contents may be used by boot control logic, attestation logic, [symbol] lock control logic, etc. The contents may include a boot up control sequence (e.g., boot up control bits), jump address(es) for each of the INST #{0, 1} bitstream location. As an example, one jump address may be associated with a current image and another jump address may be associated with a golden image. If [symbol] protection is enabled, the contents may include an RCS command protection associated with the boot up control sequence and attestation public key.

### Reading Out CRAM

The CRAM of each instance can be read out by the external System controller either by JTAG or SSPI (only if security is disabled on the instances). Various embodiments describe reading CRAM via SSPI. The following steps summarize how reading CRAM may be done for JTAG port:
Reading CRAM viaJTAG:
   Set JTAG EN=1
   CPU sends “read CRAM” command to JTAG
   INST returns the CRAM contents and CPU checks the contents

### Configuration and Context Switching After Boot Up-MSPI

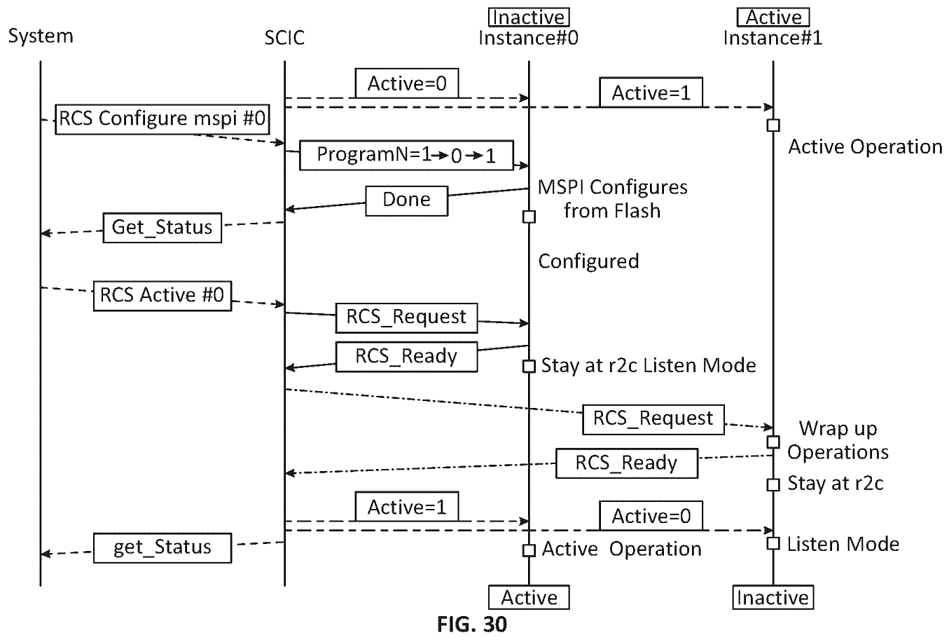

FIG. 30 illustrates a flow diagram of an example process for context switching from one PLD to another PLD in accordance with one or more embodiments of the present disclosure.
This is controlled by SCIC's RCS controller and boot controller
Boot control logic uses MSPI of INST #n to configure one instance
System (controller) sends res configure mspi #n command to CSPI of SCIC. It goes to RCS controller and it asks the boot controller to make a 1−−−−+0−−−−+1transition in programN #n pin
   The 1−−−−+0 transition starts the configuration port arbitration
   The 0−−−−+1 transition without SSPI configuration activation key enables MSPI
MSPI of INST #n works with boot controller of SCIC and reads image (e.g., FPGA image) from the flash. The offset address in flash is informed by the boot controller by sending JUMP address to CFG block
After programming, INST #n starts to run in the background with DONE asserted
System sends get_status command to CSPI to get DONE status
If DONE is asserted, system sends res activate #n command to CSPI and RCS controller starts the RCS operation
   res_request #n−−−+res_ready #n: makes the configured device go to r2c state
   rcs_request #!n−−−−+rcs_ready #!n: makes the active device go to r2c state
   active #n=1−−+active #!n=0: swap the active device with intentional overlap
System sends get_status command to CSPI to get RCS result

### SSPI to MSPI Bridge in INST #{0,1}

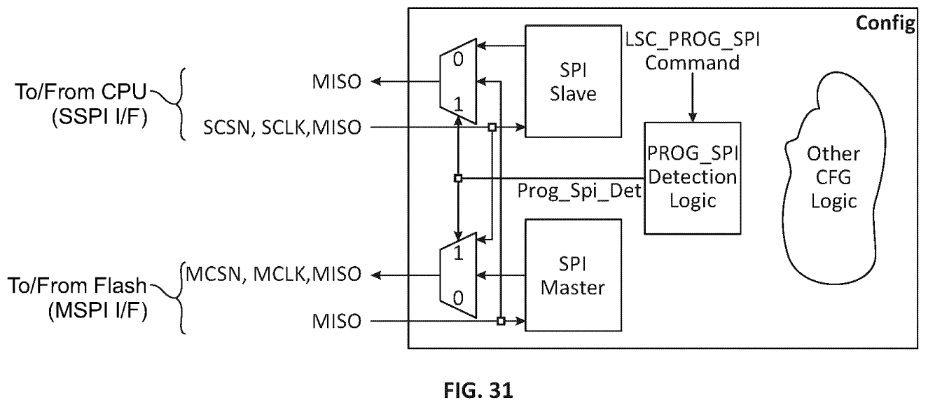

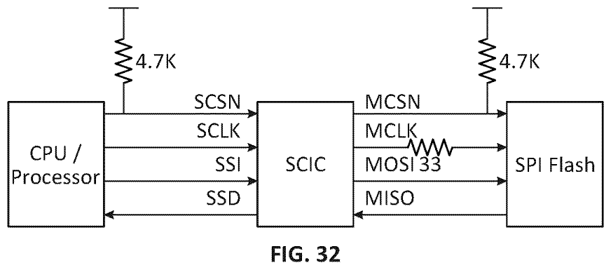

FIG. 31 illustrates an SSPI to MSPI bridge functional diagram in accordance with one or more embodiments of the present disclosure. FIG. 32 illustrates an SSPI to MSPI Bridge block diagram in accordance with one or more embodiments of the present disclosure.
Appropriate command used to enable this bridging
Deasserting CSN of SSPI terminates the operation
Boot control logic in SCIC cannot interview the MSPI operation during this mode
   No JUMP address over MISO
   No control of CSN (e.g., bypass)
SCSNs are physical signals that directly control SSPis without any possible intervention

### Pin Map and Bitstream

Bitstream and pin map are instance neutral (e.g., same bit stream and pin map for both of instances)
   Due to this, cross coupled channel between two instances may be provided
   Bitstream may use instance ID value but still implemented in the same bitstream

Where applicable, various embodiments provided by the present disclosure can be implemented using hardware, software, or combinations of hardware and software. Also where applicable, the various hardware components and/or software components set forth herein can be combined into composite components comprising software, hardware, and/or both without departing from the spirit of the present disclosure. Where applicable, the various hardware components and/or software components set forth herein can be separated into sub-components comprising software, hardware, or both without departing from the spirit of the present disclosure. In addition, where applicable, it is contemplated that software components can be implemented as hardware components, and vice-versa.

Software in accordance with the present disclosure, such as program code and/or data, can be stored on one or more non-transitory machine readable mediums. Itis also contemplated that software identified herein can be implemented using one or more general purpose or specific purpose computers and/or computer systems, networked and/or otherwise. Where applicable, the ordering of various steps described herein can be changed, combined into composite steps, and/or separated into sub-steps to provide features described herein.

Embodiments described above illustrate but do not limit the invention. It should also be understood that numerous modifications and variations are possible in accordance with the principles of the present invention. Accordingly, the scope of the invention is defined only by the following claims.

1. A system comprising:
a plurality of programmable logic devices (PLDs) each configured to be in an active state or an inactive state, wherein at most one of the plurality of PLDs is in the active state to provide PLD functionality; and
an instance controller configured to communicate with each of the plurality of PLDs and control context switch aspects to set each of the plurality of PLDs to the active state or the inactive state.

2. The system of claim 1, further comprising a memory and a multiplexer circuit configured to selectively provide access to the memory, among the plurality of PLDs, only to a PLD that is in the active state, wherein the PLD that is in the active state is configured to write data to the memory for synchronization with a PLD to be subsequently set to the active state.

3. The system of claim 1, further comprising an input/output (I/O) bank comprising a sharedI/Oconfigured to be, among the plurality of PLDs, write-accessible only to a PLD that is in the active state.

4. The system of claim 1, wherein a first PLD of the plurality of PLDs is in the active state and the remaining one or more PLDs of the plurality of PLDs is in the inactive state, and wherein the instance controller is further configured to set the first PLD to the inactive state and a second PLD of the plurality of PLDs to the active state to switch operation from the first PLD to the second PLD.

5. The system of claim 4, further comprising a memory, wherein:
the first PLD is configured to:
provide, in a first clock cycle, PLD functionality according to first configuration data loaded in the first PLD when the first PLD is in the active state; and
write synchronization data to the memory; and
the second PLD is configured to:
read the synchronize data from the memory to synchronize to the first PLD; and
provide, in a second clock cycle, PLD functionality according to second configuration data loaded in the second PLD when the second PLD is in the active state.

6. The system of claim 5, wherein the first clock cycle is adjacent to the second clock cycle.

7. The system of claim 5, wherein the first configuration data is different from the second configuration data.

8. The system of claim 5, wherein:
the first PLD is configured to:
write synchronization data to the memory in response to a first request from the instance controller to enter a ready-to-change state;
enter the ready-to-change state; and
transmit a first indication to the instance controller that the first PLD has entered the ready-to-change state; and
the second PLD is configured to:
read, in response to a second request from the instance controller, the synchronization data to synchronize the second PLD to the first PLD; and
transmit a second indication to the instance controller based on synchronization of the second PLD to the first PLD.

9. The system of claim 8, wherein the instance controller is further configured to:
receive the first and second indications; and
in response to the first and second indications, set the first PLD to the inactive state and the second PLD to the active state.

10. The system of claim 8, wherein:
the second PLD is further configured to:
enter the ready-to-change state in response to a third request from the instance controller to enter the ready-to-change state; and
transmit a third indication to the instance controller in response to entering the ready-to-change state; and
the instance controller is further configured to transmit the first request to the first PLD in response to the third indication.

11. The system of claim 5, wherein:
the first PLD is further configured to:
program configuration memory cells of the first PLD based on third configuration data when the second PLD is in the active state; and
transmit an indication to the instance controller after programming the configuration memory cells; and
the instance controller is further configured to set the first PLD to the active state and the second PLD of the plurality of PLDs to the inactive state based on the indication.

12. The system of claim 4, wherein the instance controller is further configured to set the second PLD to the inactive state and a third PLD of the plurality of PLDs to the active state to switch operation from the second PLD to the third PLD, wherein a clock of the instance controller and a clock of each of the plurality of PLDs are frequency-locked, and wherein each of the plurality of PLDs is connected to the instance controller via respective sets of connections, and wherein each set of connections is configured to handle inter-chip communication, boot control, joint test action group (JTAG) functionality, subordinate serial peripheral interface (SSPI) functionality, and/or expanded input/output (I/O), and wherein the instance controller comprises a multiplexer circuit configured to selectively support JTAG or SSPI with the plurality ofPLDs.

13. A method comprising:
operating a first programmable logic device (PLD) of a plurality of PLDs to provide PLD functionality according to fust configuration data loaded in the first PLD, wherein the first PLD of the plurality of PLDs is in an active state and the remaining one or more PLDs of the plurality of PLDs is in an inactive state, and wherein at most one of the plurality of PLDs is in the active state to provide PLD functionality; and
performing a context switch from the first PLD to a second PLD of the plurality of PLDs to set the first PLD to the inactive state and the second PLD to the active state to switch operation from the first PLD to the second PLD; and
operating the second PLD after the performing to provide PLD functionality according to second configuration data loaded in the second PLD.

14. The method of claim 13, further comprising writing, by the first PLD when the first PLD is in the active state, to a shared input/output (I/O) of an I/Obank, wherein, among the plurality of PLDs, the I/O bank is write-accessible only to a PLD that is in the active state.

15. The method of claim 13, wherein:
the first PLD is operated to provide the PLD functionality according to the first configuration data in a first clock cycle when the first PLD is in the active state; and
the performing comprises:
writing, by the first PLD, synchronization data to a memory;
reading, by the second PLD, the synchronization data from the memory; and
synchronizing, by the second PLD, the second PLD to the first PLD based on the synchronization data; and
the second PLD is operated to provide the PLD functionality according to the second configuration data in a second clock cycle when the second PLD is in the active state.

16. The method of claim 15, wherein the first clock cycle is adjacent to the second clock cycle.

17. The method of claim 15, further comprising:
entering, by the first PLD, a ready-to-change state after the writing, wherein the writing is in response to a first request from an instance controller for the first PLD to enter the ready-to-change state;
transmitting, by the first PLD, a first indication to the instance controller that the first PLD has entered the ready-to-change state;
transmitting, by the second PLD, a second indication to the instance controller based on the synchronizing; and
setting, by the instance controller in response to the first and second indications, the first PLD to the inactive state and the second PLD to the active state.

18. The method of claim 17, further comprising:
transmitting, by the instance controller, a third request to the second PLD to enter the ready-to-change state;
entering, by the second PLD, the ready-to-change state in response to the third request; and
transmitting, by the second PLD, a third indication to the instance controller in response to entering the ready-to-change state, wherein the instance controller transmits the first request to the first PLD in response to the third indication.

19. The method of claim 17, wherein the performing comprises completing, by the first PLD, on-going operations in response to the first request from the instance controller.

20. The method of claim 13, further comprising:
performing a second context switch from the second PLD to a third PLD of the plurality of PLDs to set the second PLD to the inactive state and the third PLD to the active state to switch operation from the second PLD to the third PLD; and
operating the third PLD after the second context switch to provide PLD functionality according to third configuration data loaded in the third PLD.
